(19) United States
(12) Patent Application Publication
(10) Pub. No.: US 2025/0204179 A1
(43) Pub. Date: Jun. 19, 2025

(54) DISPLAY DEVICE

(71) Applicant: Samsung Display Co., LTD., Yongin-si (KR)

(72) Inventors: Jae Woo LEE, Yongin-si (KR); Tae Ho KIM, Yongin-si (KR); Seung Jun LEE, Yongin-si (KR); Sang Min JEON, Yongin-si (KR)

(21) Appl. No.: 18/772,041

(22) Filed: Jul. 12, 2024

(30) Foreign Application Priority Data
Dec. 13, 2023 (KR) 10-2023-0180938

(51) Int. Cl. H10K 59/131

(52) U.S. Cl. CPC H10K 59/131

(57) ABSTRACT

A display device includes a substrate including a display area having emission areas, a circuit layer above the substrate, and an element layer above the circuit layer and including light-emitting elements respectively in the emission areas, wherein the circuit layer includes light-emitting pixel drivers respectively electrically connected to the light-emitting elements, and arranged in a first direction and in a second direction, data lines extending in the second direction for transmitting a data signal to the light-emitting pixel drivers, bridge lines extending in the first direction, and including a first bridge line and a second bridge line overlapping a first light-emitting pixel driver among the light-emitting pixel drivers, and auxiliary lines extending in the second direction adjacent to the data lines.

### CROSS-REFERENCE TO RELATED APPLICATION

The present application claims priority to, and the benefit of, Korean Patent Application No. 10-2023-0180938, filed on Dec. 13, 2023, in the Korean Intellectual Property Office, the entire disclosure of which is incorporated herein by reference.

### BACKGROUND

### 1. Field

The present disclosure relates to a display device.

### 2. Description of the Related Art

With the advance of information-oriented society, more and more demands are placed on display devices for displaying images in various ways. For example, display devices are employed in various electronic devices, such as smartphones, digital cameras, laptop computers, navigation devices, and smart televisions.

The display device may be a flat panel display device, such as a liquid crystal display device, a field emission display device, and a light-emitting display device. Examples of the light-emitting display device may include an organic light-emitting display device including organic light-emitting elements, an inorganic light-emitting display device including inorganic light-emitting elements, such as inorganic semiconductors, and a micro light-emitting display device including micro light-emitting elements.

The organic light-emitting display device displays an image using light-emitting elements, each including a light-emitting layer made of an organic light-emitting material. As described above, the organic light-emitting display device implements image display using a self-light-emitting element, and thus may have 1 relatively superior performance in power consumption, response speed, luminous efficiency, luminance, and wide viewing angle compared to other display devices.

One surface of the display device may include a display area in which an image is displayed and a non-display area that is a periphery of the display area.

Emission areas emitting light with respective luminances and colors may be arranged in the display area.

### SUMMARY

The display device may include data supply lines located in the non-display area of a substrate, and electrically connected between a display driving circuit and the data lines.

Because, however, the number of data lines may increase as the size and shape of the display device are variously modified, the number and extension length of data supply lines may increase and, thus, the reduction in the width of the non-display area may be limited.

In view of the above, aspects of the present disclosure provide a display device capable of reducing the width of a non-display area.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate including a display area having emission areas, a circuit layer above the substrate, and an element layer above the circuit layer and including light-emitting elements respectively in the emission areas, wherein the circuit layer includes light-emitting pixel drivers respectively electrically connected to the light-emitting elements, and arranged in a first direction and in a second direction, data lines extending in the second direction for transmitting a data signal to the light-emitting pixel drivers, bridge lines extending in the first direction, and including a first bridge line and a second bridge line overlapping a first light-emitting pixel driver among the light-emitting pixel drivers, and auxiliary lines extending in the second direction adjacent to the data lines.

The first bridge line and the second bridge line may further overlap a second light-emitting pixel driver among the light-emitting pixel drivers that is adjacent to the first light-emitting pixel driver in the first direction.

The substrate may include a main region including the display area, and a non-display area around the display area, and a sub-region at one side of the main region, wherein the display area includes a first bypass area contacting the non-display area in the first direction, and a second bypass area contacting the first bypass area in the first direction, and adjacent to the sub-region in the second direction, wherein the data lines include a first data line and a second data line adjacent to each other in the first direction in the first bypass area, and a third data line and a fourth data line adjacent to each other in the first direction in the second bypass area, wherein the first light-emitting pixel driver and the second light-emitting pixel driver are in the first bypass area, wherein the light-emitting pixel drivers include a third light-emitting pixel driver in the second bypass area and spaced apart from the first light-emitting pixel driver, and a fourth light-emitting pixel driver adjacent to the third light-emitting pixel driver in the first direction, wherein the first data line is electrically connected to at least one of the first light-emitting pixel driver or the second light-emitting pixel driver, wherein the third data line is electrically connected to at least one of the third light-emitting pixel driver or the fourth light-emitting pixel driver, and wherein the first bridge line and the second bridge line further overlap the third light-emitting pixel driver and the fourth light-emitting pixel driver.

The auxiliary lines may include a first auxiliary line overlapping the third light-emitting pixel driver, and a second auxiliary line adjacent to the first auxiliary line in the first direction, wherein the first bridge line includes a first bypass bridge line spaced 1 apart from an edge of the display area, wherein the second bridge line includes a second bypass bridge line spaced apart from the edge of the display area, wherein the first auxiliary line includes a first bypass auxiliary line electrically connected to the first bypass bridge line, and extending from one of the edges of the display area, wherein the second auxiliary line includes a second bypass auxiliary line electrically connected to the second bypass bridge line and extending from the one of the edges of the display area.

The first bridge line may further include two first additional bridge lines respectively between the first bypass bridge line and two opposing edges of the display area in the first direction, wherein the second bridge line further includes two second additional bridge lines respectively between the second bypass bridge line and the two opposing edges of the display area in the first direction, wherein the first auxiliary line further includes a first additional auxiliary line between the first bypass auxiliary line and another edge of the display area in the second direction, and wherein the second auxiliary line further includes a second additional auxiliary line between the second bypass auxiliary line and the another edge of the display area in the second direction.

The circuit layer may further include data supply lines in the non-display area, respectively electrically connected between the data lines and a display driving circuit in the sub-region, and including a first data supply line for transmitting the data signal of the first data line, a second data supply line for transmitting the data signal of the second data line, a third data supply line for transmitting the data signal of the third data line, and a fourth data supply line for transmitting the data signal of the fourth data line.

The first bypass bridge line may be electrically connected to the second data line, wherein the second bypass bridge line is electrically connected to the first data line, wherein the first data supply line is electrically connected to the first data line through the second bypass auxiliary line and the second bypass bridge line, wherein the second data supply line is electrically connected to the second data line through the first bypass auxiliary line and the first bypass bridge line, wherein the third data supply line extends to the third data line to be electrically connected to the third data line, and wherein the fourth data supply line extends to the fourth data line to be electrically connected to the fourth data line.

The first data line may be electrically connected to the first light-emitting pixel driver, wherein the second data line is electrically connected to the second light-emitting pixel driver, wherein the third data line is electrically connected to the third light-emitting pixel driver, and wherein the fourth data line is electrically connected to the fourth light-emitting pixel driver.

The circuit layer may further include scan write lines extending in the first direction for transmitting a scan write signal to the light-emitting pixel drivers, and including a first scan write line and a second scan write line that are adjacent to each other in the second direction and that overlap the first light-emitting pixel driver, the second light-emitting pixel driver, the third light-emitting pixel driver, and the fourth light-emitting pixel driver, wherein the first data line is electrically connected to the first light-emitting pixel driver and the second light-emitting pixel driver, wherein the third data line is electrically connected to the third light-emitting pixel driver and the fourth light-emitting pixel driver, wherein the first light-emitting pixel driver and the third light-emitting pixel driver are electrically connected to the first scan write line, and wherein the second light-emitting pixel driver and the fourth light-emitting pixel driver are electrically connected to the second scan write line.

The light-emitting pixel drivers may include a first transistor electrically connected between a first node electrically connected to a first electrode of the first transistor and a second node electrically connected to a second electrode of the first transistor, a pixel capacitor electrically connected between a first power line for transmitting a first power and a third node electrically connected to a gate electrode of the first transistor, and a second transistor electrically connected between a corresponding one of the data lines and the first node, wherein the second transistor of the first light-emitting pixel driver and the third light-emitting pixel driver is electrically connected to the first scan write line, and the second transistor of the second light-emitting pixel driver and the fourth light-emitting pixel driver is electrically connected to the second scan write line.

The first auxiliary line may be adjacent to the third data line on one side in the first direction, wherein the second auxiliary line is adjacent to the fourth data line on one side in the first direction.

The first bypass bridge line may be electrically connected to the second data line, wherein the second bypass bridge line is electrically connected to the first data line, wherein the first data supply line is electrically connected to the first data line through the second bypass auxiliary line and the second bypass bridge line, wherein the second data supply line is electrically connected to the second data line through the first bypass auxiliary line and the first bypass bridge line, wherein the third data supply line extends to the third data line to be electrically connected to the third data line, and the fourth data supply line extends to the fourth data line to be electrically connected to the fourth data line.

The first bypass bridge line may be electrically connected to the first data line, wherein the second bypass bridge line is electrically connected to the second data line, wherein the first data supply line is electrically connected to the first data line through the first bypass auxiliary line and the first bypass bridge line, wherein the second data supply line is electrically connected to the second data line through the second bypass auxiliary line and the second bypass bridge line, wherein the third data supply line extends to the third data line to be directly electrically connected to the third data line, and wherein the fourth data supply line extends to the fourth data line to be directly electrically connected to the fourth data line.

Two of the auxiliary lines adjacent in the first direction may be between two of the data lines adjacent in the first direction, wherein the first auxiliary line is adjacent 1 to the third data line on one side in the first direction, and wherein the second auxiliary line is adjacent to the third data line on another side in the first direction.

The first bypass bridge line may be electrically connected to the first data line, wherein the second bypass bridge line is electrically connected to the second data line, wherein the first data supply line is electrically connected to the first data line through the first bypass auxiliary line and the first bypass bridge line, and wherein the second data supply line is electrically connected to the second data line through the second bypass auxiliary line and the second bypass bridge line.

The data lines may further include a fifth data line in the second bypass area and spaced further from the first data line than the third data line in the first direction, wherein the auxiliary lines further include a third auxiliary line adjacent to the fifth data line on one side in the first direction, and a fourth auxiliary line adjacent to the fifth data line on another side in the first direction, wherein the third auxiliary line includes a third bypass auxiliary line extending from the one of the edges of the display area, wherein the fourth auxiliary line includes a fourth bypass auxiliary line extending from the one of the edges of the display area, wherein the bridge lines further include a third bridge line and a fourth bridge line that are adjacent to each other, that are spaced further from the sub-region than the second bridge line in the second direction, and that overlap the first bypass area and the second bypass area, wherein the third bridge line includes a third bypass bridge line spaced apart from the edge of the display area, wherein the fourth bridge line includes a fourth bypass bridge line spaced apart from the edge of the display area, wherein the third bypass bridge line is electrically connected between the third data line and the third bypass auxiliary line, wherein the fourth bypass bridge line is electrically connected between the fourth data line and the fourth bypass auxiliary line, wherein the third data supply line is electrically connected to the third data line through the third bypass auxiliary line and the third bypass bridge line, and wherein the fourth data supply line is electrically connected to the fourth data line through the fourth bypass auxiliary line and the fourth bypass bridge line.

An extension length of the first bypass bridge line may be greater than an extension length of the second bypass bridge line, which is greater than an extension length of the third bypass bridge line, which is in turn greater than an extension length of the fourth bypass bridge line.

An extension length of the first bypass auxiliary line may be less than an extension length of the second bypass auxiliary line, which is less than an extension length of the third bypass auxiliary line, which is in turn less than an extension length of the fourth bypass auxiliary line.

According to an aspect of the present disclosure, there is provided a display device including a substrate including a display area having emission areas, a circuit layer above the substrate, and an element layer above the circuit layer and including light-emitting elements respectively in the emission areas, wherein the circuit layer includes light-emitting pixel drivers respectively electrically connected to the light-emitting elements, and arranged in a first direction and in a second direction, scan write lines extending in the first direction for transmitting a scan write signal to the light-emitting pixel drivers, data lines extending in the second direction for transmitting a data signal to the light-emitting pixel drivers, bridge lines extending in the first direction, and auxiliary lines extending in the second direction adjacent to the data lines, wherein a first light-emitting pixel driver among the light-emitting pixel drivers is electrically connected to one of the data lines and to a first scan write line among the scan write lines, wherein a second light-emitting pixel driver among the light-emitting pixel drivers adjacent to the first light-emitting pixel driver in the first direction is electrically connected to the one of the data lines and to a second scan write line among the scan write lines adjacent to the first scan write line, wherein the light-emitting pixel drivers overlap two of the bridge lines that are adjacent in the second direction, and wherein two auxiliary lines are arranged on one side of each of the data lines in the first direction.

The substrate may include a main region including the display area and a non-display area around the display area, and a sub-region protruding from one side of the main region, wherein the display area includes a first bypass area contacting the non-display area in the first direction, and a second bypass area contacting the first bypass area in the first direction and adjacent to the sub-region in the second direction, wherein the data lines include a first data line and a second data line in the first bypass area and adjacent to each other in the first direction, a third data line and a fourth data line in the second bypass area and adjacent to each other in the first direction, and a fifth data line in the second bypass area and spaced further from the first data line than the third data line in the first direction, wherein the bridge lines include a first bridge line and a second bridge line adjacent in the second direction and overlapping the first bypass area and the second bypass area, and a third bridge line and a fourth bridge line adjacent in the second direction, spaced further from the sub-region than the second bridge line, and overlapping the first bypass area and the second bypass area, wherein the first bridge line, the second bridge line, the third bridge line, and the fourth bridge line respectively include a first bypass bridge line, a second bypass bridge line, a third bypass bridge line, and a fourth bypass bridge line spaced apart from an edge of the display area, wherein the auxiliary lines include a first auxiliary line adjacent to the third data line on one side in the first direction, a second auxiliary line adjacent to the third data line on another side in the first direction, a third auxiliary line adjacent to the fifth data line on one side in the first direction, and a fourth auxiliary line adjacent to the fifth data line on another side in the first direction, wherein the first auxiliary line, the second auxiliary line, the third auxiliary line, and the fourth auxiliary line respectively include a first bypass auxiliary line, a second bypass auxiliary line, a third bypass auxiliary line, and a fourth bypass auxiliary line extending from one of the edges of the display area, wherein the first bypass bridge line is electrically connected between the first data line and the first bypass auxiliary line, wherein the second bypass bridge line is electrically connected between the second data line and the second bypass auxiliary line, wherein the third bypass bridge line is electrically connected between the third data line and the third bypass auxiliary line, wherein the fourth bypass bridge line is electrically connected between the fourth data line and the fourth bypass auxiliary line, wherein an extension length of the fourth bypass bridge line is less than an extension length of the third bypass bridge line, which is less than an extension length of the second bypass bridge line, which is less than an extension length of the first bypass bridge line.

However, aspects according to the embodiments of the present disclosure are not limited to those described above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a plan view illustrating a display device according to embodiments;

FIG. 2 is a cross-sectional view taken along the line A-A′ of FIG. 1;

FIG. 3 is a layout diagram illustrating part B of FIG. 1;

FIG. 4 is an equivalent circuit diagram showing the light-emitting pixel driver of FIG. 3;

FIG. 5 is a cross-sectional view showing the light-emitting element and the first and sixth transistors of FIG. 4;

FIG. 6 is a layout diagram showing part C of FIG. 1 according to one or more embodiments;

FIG. 7 is a cross-sectional view taken along the line D-D′ of FIG. 6;

FIG. 8 is a layout diagram showing part C of FIG. 1 according to one or more embodiments;

FIG. 9 is a layout diagram illustrating part E of FIG. 8;

FIG. 10 is a layout diagram showing part C of FIG. 1 according to one or more embodiments;

FIG. 11 is a layout diagram showing part C of FIG. 1 according to one or more embodiments;

FIG. 12 is a layout diagram illustrating part F of FIG. 11; and

FIG. 13 is a layout diagram illustrating part G of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present.

The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, specific embodiments will be described with reference to the accompanying drawings.

A display device according to embodiments includes a substrate, a circuit layer located on the substrate, and an element layer located on the circuit layer. The substrate may include a display area in which emission areas are arranged. The element layer may include light-emitting elements respectively located in to the emission areas. The circuit layer may include light-emitting pixel drivers respectively electrically connected to the light-emitting elements, and arranged side by side with each other in a first direction and a second direction, data lines extending in the second direction, and transmitting a data signal to the light-emitting pixel drivers, bridge lines extending in the first direction, and auxiliary lines extending in the second direction, and adjacent to the data lines. Each of the light-emitting pixel drivers may overlap two bridge lines adjacent in the second direction among the bridge lines.

That is, in accordance with embodiments, each light-emitting pixel driver might not overlap one bridge line, but instead may overlap two bridge lines.

In this way, the number of bridge lines may be doubled, compared to the case where each light-emitting pixel driver overlaps one bridge line. Therefore, even when the number of data lines is greater than the number of sub-pixel columns each including light-emitting pixel drivers arranged in a first direction due to the shape and size of the display area, electrical connection between at least some data lines and at least some bridges lines may be implemented.

According to embodiments, the circuit layer may further include scan write lines extending in the first direction for transmitting a scan write signal to the light-emitting pixel drivers. Each of the light-emitting pixel drivers may overlap two scan write lines adjacent in the second direction among the scan write lines. That is, among the light-emitting pixel drivers, the first light-emitting pixel driver and the second light-emitting pixel driver adjacent to each other in the first direction may be electrically connected to a first data line among the data lines. The first light-emitting pixel driver may be electrically connected to a first scan write line among scan write lines. The second light-emitting pixel driver may be electrically connected to a second scan write line adjacent to the first scan write line in a second direction among the scan write lines.

In this way, the number of data lines may be reduced to half of the number of sub-pixel rows each including light-emitting pixel drivers arranged in the second direction. Therefore, the influence of the shape and size of the display area on the implementation of the electrical connection between at least some data lines and at least some bridge lines may be reduced.

In accordance with embodiments, two auxiliary lines adjacent in the first direction may be located between two data lines adjacent in the first direction among the data lines.

That is, the auxiliary lines may include a first auxiliary line adjacent to one side in the first direction of a third data line located adjacent to a sub-region compared to the first data line among the data lines, a second auxiliary line adjacent to the other side in the first direction of the third data line, a third auxiliary line spaced further apart from the first data line in the first direction than the third data line among the data lines and adjacent to one side in the first direction of a fifth data line located adjacent to the third data line, and a fourth auxiliary line adjacent to the other side of the fifth data line.

In this way, all the data lines may be electrically connected to the data supply lines through bypass bridge lines of the bridge lines and bypass auxiliary lines of the auxiliary lines.

That is, the first data line may be electrically connected to a first data supply line through the bypass bridge line of a first bridge line and the bypass auxiliary line of the first auxiliary line.

Similarly, the third data line may be electrically connected to a third data supply line through the bypass bridge line of a third bridge line and the bypass auxiliary line of the third auxiliary line.

Accordingly, the difference in resistances of signal transmission paths between the data lines and the display driving circuit may be reduced and, thus, the difference in distortion or delay of a data signal may be reduced, thereby improving the display quality of the display device.

However, aspects according to the embodiments of the present disclosure are not limited to those described above and various other aspects are incorporated herein.

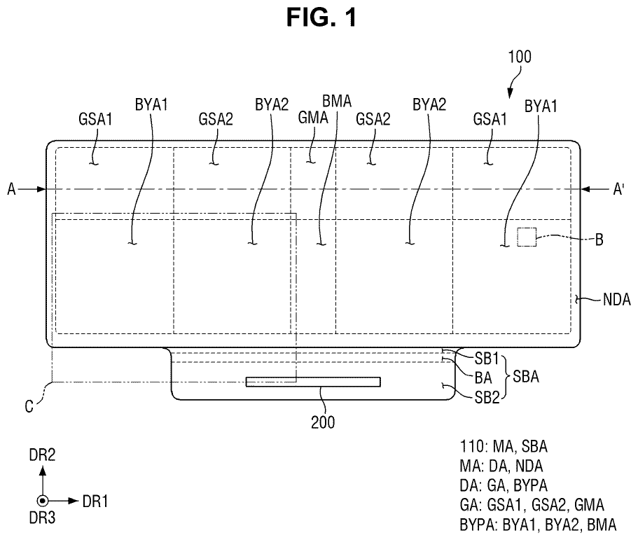

FIG. 1 is a plan view illustrating a display device according to embodiments.

As a device for displaying a moving image or a still image, it may be used as a display screen of various products, such as televisions, laptop computers, monitors, billboards and the Internet of Things (IoT) as well as portable electronic devices, such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs).

A display device 100 may be a light-emitting display device, such as an organic light-emitting display using an organic light-emitting diode, a quantum dot light-emitting display including a quantum dot light-emitting layer, an inorganic light-emitting display including an inorganic semiconductor, and a micro light-emitting display using a micro or nano light-emitting diode (LED). In the following description, it is assumed that the display device 100 is an organic light-emitting display device. However, the present disclosure is not limited thereto, and may be applied to a display device including an organic insulating material, an organic light-emitting material, and a metal material.

The display device 100 may be formed to be flat, but is not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 1, the display device 100 according to one or more embodiments may include a substrate 110.

The substrate 110 may include a main region MA corresponding to a display surface of the display device 100 and a sub-region SBA protruding from one side of the main region MA.

The main region MA may include a display area DA located at most of the center of the main region MA, and a non-display area NDA located around the display area DA.

The substrate 110 may be prepared as a rectangular plane. One surface of the substrate 110 may correspond to a display surface through which light for image display is emitted. Most of the area located in the center of the display surface may be the display area DA.

The display area DA may have a shape similar to that of the substrate 110. For example, each of the substrate 110 and the display area DA may have a shape similar to a quadrangle having two relatively short sides extending in a second direction DR2 and two relatively long sides extending in a first direction DR1.

The corner where two sides extending in different directions meet each other among respective edges of the substrate 110 and the display area DA may be right-angled, or may be rounded to have a curvature (e.g., predetermined curvature). The shape of the display area DA is not limited to a quadrangle with four sides, and may be a circle, an ellipse, or a polygon other than a quadrangle.

The non-display area NDA may be located around the display area DA. That is, the non-display area NDA may be located between the edge of the display area DA and the edge of the substrate 110 to surround the display area DA.

The sub-region SBA may be a region protruding from the non-display area NDA of the main region MA to one side in the second direction DR2. Because a part of the sub-region SBA is transformed into a curved shape, another part of the sub-region SBA may be located on the rear surface of the substrate 110 that is opposite to the display surface. The sub-region SBA may include a bending region BA that is transformed into a bending shape, a first sub-region SB1 located between one side of the bending region BA and the main region MA, and a second sub-region SB2 connected to the other side of the bending region BA.

When the bending region BA is transformed into a bending shape, the second sub-region SB2 may be located below the substrate 110, and may overlap the main region MA.

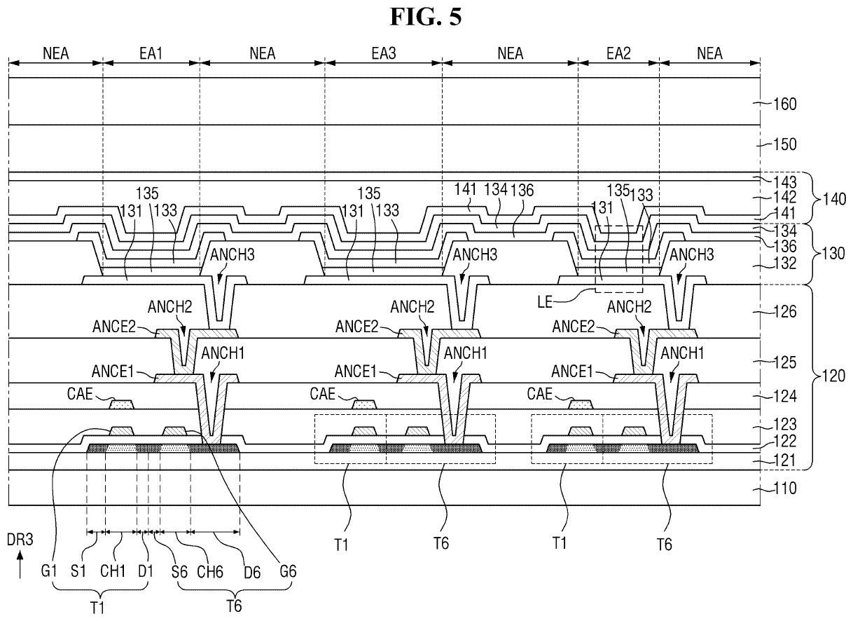

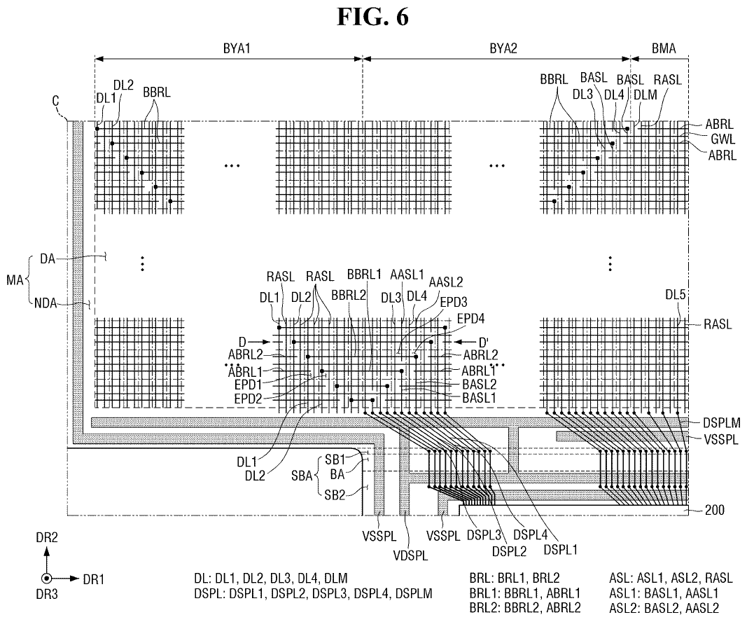

In accordance with embodiments, the display device 100 may further include a display driving circuit 200 located in the sub-region SBA. The display driving circuit 200 may be located in the second sub-region SB2 of the sub-region SBA, and may output a data signal Vdata (see FIG. 5) of each of data lines DL (see FIGS. 5 and 6).

The display area DA may include a bypass area BYPA located on one side adjacent to the sub-region SBA in the second direction DR2, and a general area GA that is the remaining area except the bypass area BYPA.

Wires electrically connected between the data lines DL and the display driving circuit 200 of the sub-region SBA may be located in the bypass area BYPA. The bypass area BYPA may include a first bypass area BYA1 contacting the non-display area NDA in the first direction DR1, and a second bypass area BYA2 contacting the first bypass area BYA1 in the first direction DR1 and located adjacent to the sub-region SBA in the second direction DR2. The first bypass area BYA1 may be located between the non-display area NDA and the second bypass area BYA2 in the first direction DR1. That is, the display area DA may include the first bypass area BYA1 and the second bypass area BYA2 adjacent in the first direction DR1. The bypass area BYPA may include two first bypass areas BYA1 and two second bypass areas BYA2 located on respective sides in the first direction DR1. Further, the bypass area BYPA may further include a bypass middle area BMA located between the two second bypass areas BYA2.

The general area GA may include a first general side area GSA1 located between the first bypass area BYA1 and the non-display area NDA in the second direction DR2, a second general side area GSA2 located between the second bypass area BYA2 and the non-display area NDA in the second direction DR2, and a general middle area GMA located between the bypass middle area BMA and the non-display area NDA in the second direction DR2.

In accordance with embodiments, the display device 100 may be a foldable device or a flip device that may be transformed into a folded shape or an unfolded shape with respect to at least one display bending area where the main region MA of the substrate 110 extends in one of the first direction DR1 and the second direction DR2. Alternatively, the display device 100 may be a slidable device in which at least a part of the main region MA of the substrate 110 may be transformed into a rolled shape or an unfolded shape.

Accordingly, a part of the main region MA may be transformed into an unfolded shape, a folded shape, or a rolled shape, and the sub-region SBA may be spaced apart from the transformed part of the main region MA. For example, when the transformed part of the main region MA extends in the first direction DR1, the sub-region SBA may protrude from the side extending in the first direction DR1 among the edges of the main region MA. Alternatively, when the sub-region SBA protrudes from the side extending in the second direction DR2 among the edges of the main region MA, the sub-region SBA may be spaced apart from the transformed part of the main region MA in the first direction DR1.

Further, as shown in FIG. 1, the main region MA of the substrate 110 may have a width in the first direction DR1 that is greater than twice the width in the second direction DR2.

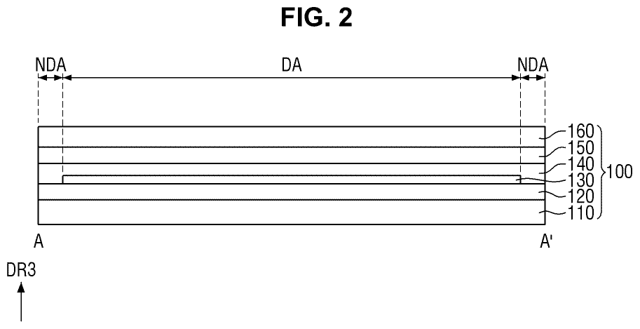

FIG. 2 is a cross-sectional view taken along the line A-A′ of FIG. 1.

Referring to FIG. 2, the display device 100 according to one or more embodiments includes the substrate 110, a circuit layer 120 located on the substrate 110, and an element layer 130 located on the circuit layer 120 (as used herein, “located on” may mean “above”). The display device 100 may further include an encapsulation layer 140 covering the element layer 130, and a touch sensor layer 150 located on the encapsulation layer 140. The display device 100 may further include a polarization layer 160 located on the touch sensor layer 150 to reduce reflection of external light.

The substrate 110 may be formed of an insulating material, such as a polymer resin. For example, the substrate 110 may be formed of polyimide. The substrate 110 may be a flexible substrate which can be bent, folded or rolled.

Alternatively, the substrate 110 may be formed of an insulating material, such as glass or the like. The substrate 110 may include the display area DA and the non-display area NDA.

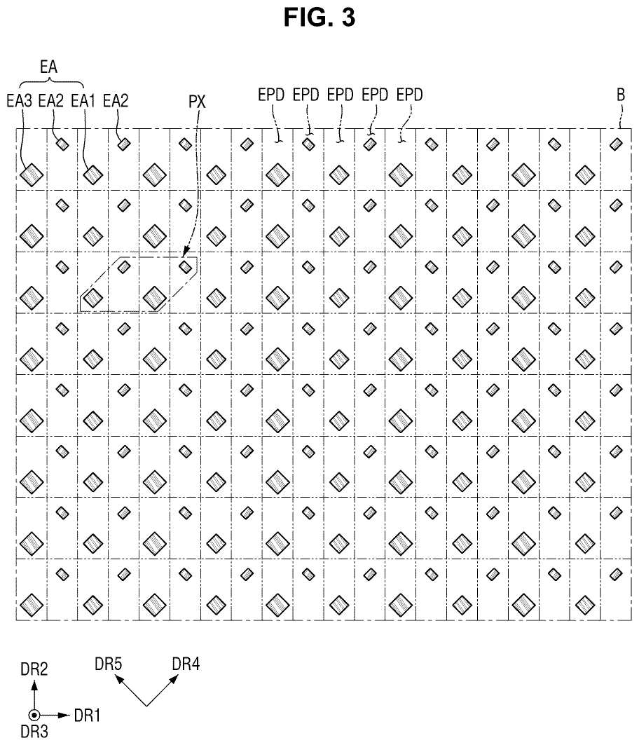

The circuit layer 120 may include light-emitting pixel drivers EPD (see FIG. 3) for adjusting luminances of respective emission areas EA (see FIG. 3).

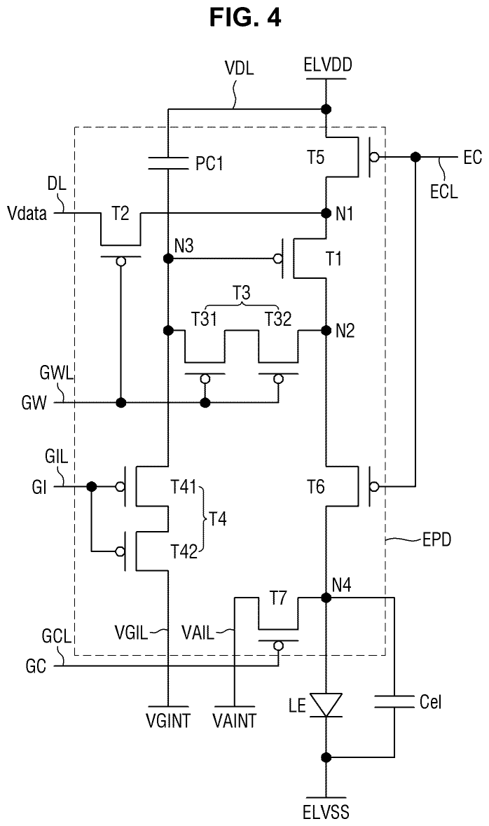

The element layer 130 may include light-emitting elements LE (see FIGS. 4 and 5) electrically connected to the light-emitting pixel drivers EPD (see FIG. 3).

The encapsulation layer 140 may have a structure in which insulating layers having different materials or thicknesses are stacked.

The touch sensor layer 150 may include touch electrodes and touch lines for sensing and outputting a capacitance at each point that varies by touch.

FIG. 3 is a layout diagram illustrating part B of FIG. 1.

Referring to FIG. 3, the display area DA of the substrate 110 according to one or more embodiments may include emission areas EA. The display area DA may further include a non-emission area located in a gap between the emission areas EA.

The emission areas EA may have a rhombus shape or a rectangular shape in plan view. However, this is only an example, and the planar shape of the emission areas EA according to one or more embodiments is not limited to that illustrated in FIG. 3. That is, in plan view, the emission areas EA may have a polygonal shape, such as a square, a pentagon, a hexagon, etc., or may have a circular or elliptical shape including the edge of a curve. The emission areas EA may include first emission areas EA1 emitting light of a first color in a wavelength band (e.g., predetermined wavelength band), second emission areas EA2 emitting light of a second color in a wavelength band that is lower than that of the first color, and third emission areas EA3 emitting light of a third color in a wavelength band that is lower than that of the second color.

For example, the first color may be red having a wavelength band of approximately 600 nm to approximately 750 nm. The second color may be green having a wavelength band of approximately 480 nm to approximately 560 nm. The third color may be blue having a wavelength band of approximately 370 nm to approximately 460 nm.

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2. In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA. In other words, the pixels PX may be a basic unit for displaying various colors including white with a luminance (e.g., predetermined luminance). Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

According to embodiments, the element layer 130 (see FIG. 2) may include light-emitting elements LE (see FIGS. 5 and 6) respectively located in the emission areas EA, and the circuit layer 120 may include the light-emitting pixel drivers EPD that are respectively electrically connected to the light-emitting elements LE of the element layer 130. The light-emitting pixel drivers EPD may be arranged side by side in the first direction DR1 and the second direction DR2.

FIG. 4 is an equivalent circuit diagram showing the light-emitting pixel driver of FIG. 3.

Referring to FIG. 4, one of the light-emitting elements LE of the element layer 130 may be electrically connected between one of the light-emitting pixel drivers EPD of the circuit layer 120 and a second power ELVSS.

That is, the anode electrode of the light-emitting element LE is electrically connected to the light-emitting pixel driver EPD, and the cathode electrode of the light-emitting element LE may be applied with the second power ELVSS lower than a first power ELVDD.

A capacitor Cel indicated in parallel with the light-emitting element LE refers to a parasitic capacitance between an anode electrode 131 and a cathode electrode 134 (e.g., see FIG. 5).

The circuit layer 120 may include the light-emitting pixel drivers EPD that are respectively electrically connected to the light-emitting elements LE of the element layer 130, a scan write line GWL for transmitting a scan write signal GW to the light-emitting pixel driver EPD, and the data line DL for transmitting the data signal Vdata to the light-emitting pixel drivers EPD.

The circuit layer 120 may further include a scan initialization line GIL for transmitting a scan initialization signal GI, an emission control line ECL for transmitting an emission control signal EM, and a gate control line GCL for transmitting a gate control signal GC. The circuit layer 120 may further include a first power line VDL for transmitting the first power ELVDD, a gate initialization voltage line VGIL for transmitting a gate initialization voltage VGINT, and an anode initialization voltage line VAIL for transmitting an anode initialization voltage VAINT.

Each of the light-emitting pixel drivers EPD of the circuit layer 120 may include a first transistor T1 electrically connected between a first node N1 and a second node N2, a pixel capacitor PC1 electrically connected between the first power line VDL and a third node N3, and a second transistor T2 electrically connected between the data line DL and the first node N1.

The first node N1 is electrically connected to the first electrode of the first transistor T1. The second node N2 is electrically connected to the second electrode of the first transistor T1. The third node N3 is electrically connected to the gate electrode of the first transistor T1.

Each of the light-emitting pixel drivers EPD may further include third to sixth transistors T3, T4, T5, and T6 electrically connected to one of the first node N1, the second node N2, and the third node N3, and a seventh transistor T7 electrically connected to a fourth node N4 to initialize or stably maintain the potential of each node. The fourth node N4 is electrically connected to the anode electrode of the light-emitting element LE.

The first transistor T1 generates a driving current corresponding to the data signal Vdata. The first electrode (e.g., the source electrode) of the first transistor T1 may be electrically connected to the first power line VDL through the fifth transistor T5. Further, the second electrode (e.g., the drain electrode) of the first transistor T1 may be electrically connected to the fourth node N4 (e.g., the anode electrode of the light-emitting element LE) through the sixth transistor T6.

The second transistor T2 may be electrically connected between the first electrode of the first transistor T1 and the data line DL. The second transistor T2 may be turned on by the scan write signal GW of the scan write line GWL.

The third transistor T3 may be electrically connected between the gate electrode of the first transistor T1 and the second electrode of the first transistor T1. The third transistor T3 may be turned on by the scan write signal GW of the scan write line GWL. The third transistor T3 may include a plurality of sub-transistors connected in series. For example, the third transistor T3 may include a first sub-transistor T31 and a second sub-transistor T32. In this way, it is possible to reduce or prevent the potential of the gate electrode of the first transistor T1 from changing due to leakage current through the third transistor T3 that is turned off.

The fourth transistor T4 may be connected between the gate electrode of the first transistor T1 and the gate initialization voltage line VGIL. The fourth transistor T4 may be turned on by the scan initialization signal GI of the scan initialization line GIL. The fourth transistor T4 may include a plurality of sub-transistors connected in series. For example, the fourth transistor T4 may include a third sub-transistor T41 and a fourth sub-transistor T42. In this way, it is possible to reduce or prevent the potential of the gate electrode of the first transistor T1 from changing due to leakage current through the fourth transistor T4 that is turned off.

The fifth transistor T5 may be electrically connected between the first electrode of the first transistor T1 and the first power line VDL. The sixth transistor T6 may be electrically connected between the second electrode of the first transistor T1 and the anode electrode 131 of the light-emitting element LE. The fifth transistor T5 and the sixth transistor T6 may be turned on by the emission control signal EC of the emission control line ECL.

The seventh transistor T7 may be electrically connected between the anode electrode 131 of the light-emitting element LE and the anode initialization voltage line VAIL. The seventh transistor T7 may be turned on by the gate control signal GC of the gate control line GCL.

The gate electrode of the first transistor T1 may be electrically connected to the first power line VDL through the pixel capacitor PC1. That is, the pixel capacitor PC1 is electrically connected between the first power line VDL and the gate electrode of the first transistor T1, so that the potential of the gate electrode of the first transistor T1 may be maintained by the first power ELVDD of the first power line VDL.

The first electrode of the first transistor T1 may be electrically connected to the data line DL through a second transistor T2. Accordingly, when the data signal Vdata of the data line DL is transmitted to the first electrode of the first transistor T1 through the turned-on second transistor T2, a voltage difference between the gate electrode of the first transistor T1 and the first electrode of the first transistor T1 may correspond to the first power ELVDD and the data signal Vdata. In this case, when the voltage difference between the gate electrode of the first transistor T1 and the first electrode of the first transistor T1 (e.g., the gate-source voltage difference becomes equal to or greater than a threshold voltage) the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light-emitting element LE between the first power ELVDD and the second power ELVSS. Accordingly, the drain-source current of the first transistor T1 corresponding to the data signal Vdata may be supplied as a driving current of the light-emitting element LE. Accordingly, the light-emitting element LE may emit light having a luminance corresponding to the data signal Vdata.

As shown in FIG. 4, the first to seventh transistors T1, T2, T3, T4, T5, T6, and T7 may be provided as P-type MOSFETs. However, this is merely an example, and one or more of the first to seventh transistors T1, T2, T3, T4, T5, T6, or T7 may be provided as N-type MOSFETs. For example, among the first to seventh transistors T1, T2, T3, T4, T5, T6, and T7, the third transistor T3 and the fourth transistor T4 may be provided as N-type MOSFETs.

FIG. 5 is a cross-sectional view showing the light-emitting element and the first and sixth transistors of FIG. 4.

Referring to FIG. 5, the display device 100 according to one or more embodiments may include the substrate 110, the circuit layer 120 on the substrate 110, and the element layer 130 on the circuit layer 120 (as used herein, “on” may mean “above”). In addition, the display device 100 may further include the encapsulation layer 140 located on the element layer 130, the touch sensor layer 150 located on the encapsulation layer 140, and the polarization layer 160 located on the touch sensor layer 150.

In accordance with embodiments, the circuit layer 120 may include a semiconductor layer CH1, S1, D1, CH6, S6, and D6 located on the substrate 110, a first gate-insulating layer 122 covering the semiconductor layer, a first gate conductive layer G1 and G6 located on the first gate-insulating layer 122, a second gate-insulating layer 123 covering the first gate conductive layer, a second gate conductive layer CAE located on the second gate-insulating layer 123, an interlayer insulating layer 124 covering the second gate conductive layer, a first source-drain conductive layer ANCE1 located on the interlayer insulating layer 124, a first planarization layer 125 covering the first source-drain conductive layer, a second source-drain conductive layer ANCE2 located on the first planarization layer 125, and a second planarization layer 126 covering the second source-drain conductive layer.

The circuit layer 120 may further include the buffer layer 121 covering the substrate 110. In this case, the semiconductor layer may be located on the buffer layer 121.

The circuit layer 120 may include the light-emitting pixel drivers EPD that are respectively electrically connected to the light-emitting elements LE located in the emission areas EA, and wires for transmitting various signals and voltages to the light-emitting pixel drivers EPD. The light-emitting pixel drivers EPD may include two or more transistors T1, T2, T3, T4, T5, T6, and T7.

According to embodiments, the first transistor T1 may include a channel portion CH1, a source portion S1, and a drain portion D1 located in the semiconductor layer on the substrate 110, and a gate electrode G1 located in the first gate conductive layer on the first gate-insulating layer 122.

In the first transistor T1, the source portion S1 and the drain portion D1 may be connected to respective ends of the channel portion CH1. The source portion S1 and the drain portion D1 may be doped at a higher concentration than the channel portion CH1. The gate electrode G1 may overlap the channel portion CH1.

Similarly, the sixth transistor T6 may include a channel portion CH6, a source portion S6, and a drain portion D6 located in the semiconductor layer on the substrate 110, and a gate electrode G6 located in the first gate conductive layer on the first gate-insulating layer 122 covering the semiconductor layer.

The source portion S6 of the sixth transistor T6 may be connected to the drain portion D1 of the first transistor T1. The drain portion D6 of the sixth transistor T6 may be electrically connected to the anode electrode 131 of the element layer 130 through a first anode connection electrode ANCE1 and a second anode connection electrode ANCE2.

The first anode connection electrode ANCE1 may be located on a first source-drain conductive layer on the interlayer insulating layer 124 covering the second gate conductive layer. The first anode connection electrode ANCE1 may be electrically connected to the drain portion D6 of the sixth transistor T6 through a first anode contact hole ANCH1 penetrating the interlayer insulating layer 124, the second gate-insulating layer 123, and the first gate-insulating layer 122.

The second anode connection electrode ANCE2 may be located on a second source-drain conductive layer on the first planarization layer 125 covering the first source-drain conductive layer. The second anode connection electrode ANCE2 may be electrically connected to the first anode connection electrode ANCE1 through a second anode contact hole ANCH2 penetrating the first planarization layer 125.

According to embodiments, the second to fifth transistors T2, T3, T4, and T5 and the seventh transistor T7 have substantially the same structure as the first transistor T1 and the sixth transistor T6, and therefore, redundant description will be omitted below.

The pixel capacitor PC1 (e.g., see FIG. 4) may be provided as an overlapping area between the gate electrode G1 of the first transistor T1 and a pixel capacitor electrode CAE. The pixel capacitor electrode CAE may be located in the second gate conductive layer on the second gate-insulating layer 123.

The element layer 130 may include light-emitting elements LE respectively corresponding to the emission areas EA. Each of the light-emitting elements LE may include the anode electrode 131 and the cathode electrode 134 facing each other, and a light-emitting layer 133 located therebetween.

Alternatively, each of the light-emitting elements LE may further include a first common layer 135 located between the anode electrode 131 and the light-emitting layer 133, and a second common layer 136 located between the light-emitting layer 133 and the cathode electrode 134.

That is, the element layer 130 may include the anode electrodes 131 located on the second planarization layer 126 and respectively corresponding to the emission areas EA, a pixel-defining layer 132 corresponding to a non-emission area NEA and covering the edge of the anode electrode 131, the light-emitting layers 133 respectively located on the anode electrodes 131, and the cathode electrode 134 located on the light-emitting layers 133 and the pixel-defining layer 132.

The anode electrode 131 may be located in each of the emission areas EA and may be electrically connected to one light-emitting pixel driver EPD of the circuit layer 120. This anode electrode 131 may be referred to as a pixel electrode. The anode electrode 131 may be electrically connected to the second anode connection electrode ANCE2 through a third anode contact hole ANCH3 penetrating the second planarization layer 126.

The light-emitting layer 133 may be formed of an organic light-emitting material that converts electron-hole pairs into light.

The cathode electrode 134 may be located on the pixel-defining layer 132 and the light-emitting layers 133 of the emission areas EA. The second power ELVSS may be applied to the cathode electrode 134. The cathode electrode 134 may be referred to as a common electrode.

The encapsulation layer 140 may be located on the circuit layer 120 and cover the element layer 130. The encapsulation layer 140 may include a first encapsulation layer 141 located on the element layer 130 and made of an inorganic insulating material, a second encapsulation layer 142 located on the first encapsulation layer 141, overlapping the element layer 130, and made of an organic insulating material, and a third encapsulation layer 143 located on the first encapsulation layer 141, covering the second encapsulation layer 142, and made of an inorganic insulating material.

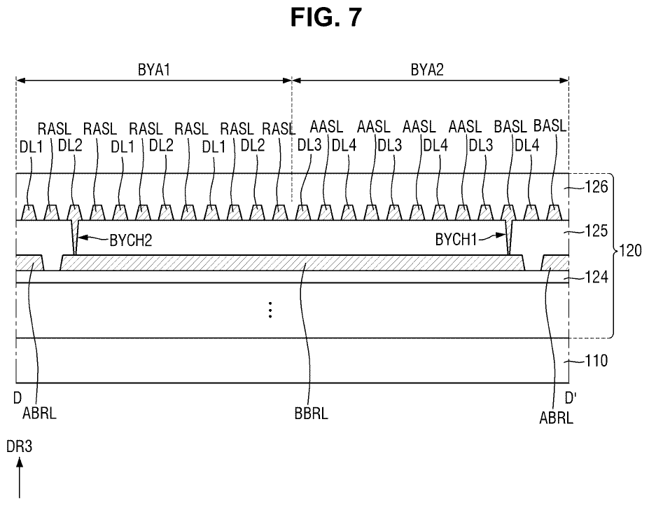

FIG. 6 is a layout diagram showing part C of FIG. 1 according to one or more embodiments. FIG. 7 is a cross-sectional view taken along the line D-D′ of FIG. 6.

Referring to FIG. 6, the circuit layer 120 of the display device 100 according to embodiments may include the light-emitting pixel drivers EPD arranged in the first direction DR1 and the second direction DR2, the data lines DL extending in the second direction DR2 for transmitting the data signal Vdata to the light-emitting pixel drivers EPD, the bridge lines BRL extending in the first direction DR1, and auxiliary lines ASL extending in the second direction DR2 and adjacent to the data lines DL.

In accordance with embodiments, each of the light-emitting pixel drivers EPD may overlap two bridge lines BRL1 and BRL2 adjacent in the second direction DR2 among the bridge lines BRL.

That is, the bridge lines BRL may overlap a first light-emitting pixel driver EPD1 and a second light-emitting pixel driver EPD2 adjacent in the first direction DR1 among the light-emitting pixel drivers EPD, and may include a first bridge line BRL1 and a second bridge line BRL2 adjacent to each other in the second direction DR2.

The first bridge line BRL1 may be closer to the sub-region SBA than the second bridge line BRL2.

The display area DA of the substrate 110 may include the first bypass area BYA1 contacting the non-display area NDA in the first direction DR1, and the second bypass area BYA2 contacting the first bypass area BYA1 in the first direction DR1 and located adjacent to the sub-region SBA in the second direction DR2.

In accordance with embodiments, the light-emitting pixel drivers EPD may include the first light-emitting pixel driver EPD1 and the second light-emitting pixel driver EPD2 located in the first bypass area BYA1 and adjacent to each other in the first direction DR1, a third light-emitting pixel driver EPD3 located in the second bypass area BYA2 to be arranged side by side with the first light-emitting pixel driver EPD1 in the first direction DR1 and spaced apart from the first light-emitting pixel driver EPD1, and a fourth light-emitting pixel driver EPD4 adjacent to the third light-emitting pixel driver EPD3 in the first direction DR1.

Because the third light-emitting pixel driver EPD3 and the fourth light-emitting pixel driver EPD4 are arranged side by side with the first light-emitting pixel driver EPD1 in the first direction DR1, the first bridge line BRL1 and the second bridge line BRL2 may further overlap the third light-emitting pixel driver EPD3 and the fourth light-emitting pixel driver EPD4.

The data lines DL may include a first data line DL1 and a second data line DL2 located in the first bypass area BYA1 and adjacent to each other in the first direction DR1, and a third data line DL3 and a fourth data line DL4 located in the second bypass area BYA2 and adjacent to each other in the first direction DR1.

The first data line DL1 of the first bypass area BYA1 may be electrically connected to at least one of the first light-emitting pixel driver EPD1 or the second light-emitting pixel driver EPD2. The third data line DL3 of the second bypass area BYA2 may be electrically connected to at least one of the third light-emitting pixel driver EPD3 or the fourth light-emitting pixel driver EPD4.

As shown in FIG. 6, in accordance with one or more embodiments, the light-emitting pixel drivers EPD arranged in the first direction DR1 may be electrically connected to different data lines DL. For example, the first data line DL1 may be electrically connected to the first light-emitting pixel driver EPD1, the second data line DL2 may be electrically connected to the second light-emitting pixel driver EPD2, the third data line DL3 may be electrically connected to the third light-emitting pixel driver EPD3, and the fourth data line DL4 may be electrically connected to the fourth light-emitting pixel driver EPD4.

In accordance with embodiments, the auxiliary lines ASL may include a first auxiliary line ASL1 overlapping the third light-emitting pixel driver EPD3, and a second auxiliary line ASL2 overlapping the fourth light-emitting pixel driver EPD4.

In accordance with the one or more embodiments corresponding to FIG. 6, the first auxiliary line ASL1 may be adjacent to the third data line DL3, and the second auxiliary line ASL2 may be adjacent to the fourth data line DL4.

Some bypass bridge lines located in the bypass area BYPA among the bridge lines BRL may include a bypass bridge line BBRL extending between the first bypass area BYA1 and the second bypass area BYA2. That is, the first bridge line BRL1 and the second bridge line BRL2 may include a bypass bridge line BBRL1 and a bypass bridge line BBRL2 spaced apart from the edge of the display area DA, respectively.

Each of some bypass bridge lines located in the bypass area BYPA among the bridge lines BRL may further include two additional bridge lines ABRL located between the bypass bridge line BBRL and two edges facing each other in the first direction among the edges of the display area DA. That is, the additional bridge lines ABRL may be located between both ends of the bypass bridge line BBRL and the non-display area NDA.

In other words, the first bridge line BRL1 may include the bypass bridge line BBRL1 overlapping the first bypass area BYA1 and the second bypass area BYA2, and two additional bridge lines ABRL1 extending from respective ends (e.g., from near respective ends) of the bypass bridge line BBRL1 to the non-display area NDA. Similarly, the second bridge line BRL2 may include the bypass bridge line BBRL2 overlapping the first bypass area BYA1 and the second bypass area BYA2, and two additional bridge lines ABRL2 extending from/from near respective ends thereof to the non-display area NDA.

Each of some auxiliary lines located in the second bypass area BYA2 among the auxiliary lines ASL may include a bypass auxiliary line BASL extending from one edge facing the sub-region SBA among the edges of the display area DA. That is, the first auxiliary line ASL1 and the second auxiliary line ASL2 may include a bypass auxiliary line BASL1 and a bypass auxiliary line BASL2 extending from one of the edges of the display area DA, respectively.

Each of some auxiliary lines located in the second bypass area BYA2 among the auxiliary lines ASL may further include an additional auxiliary line AASL located between the bypass auxiliary line BASL and another edge facing one edge in the second direction DR2 among the edges of the display area DA. That is, the additional auxiliary line AASL may be located between the bypass auxiliary line BASL and the non-display area NDA.

In other words, the first auxiliary line ASL1 overlapping the third light-emitting pixel driver EPD3 may include the bypass auxiliary line BASL1 located in the bypass area BYPA, and an additional auxiliary line AASL1 extending from one end thereof to the non-display area NDA. Similarly, the second auxiliary line ASL2 overlapping the fourth light-emitting pixel driver EPD4 may include the bypass auxiliary line BASL2 located in the bypass area BYPA, and an additional auxiliary line AASL2 extending from one end thereof to the non-display area NDA.

The bypass bridge line BBRL1 of the first bridge line BRL1 may be electrically connected to the bypass auxiliary line BASL1 of the first auxiliary line ASL1. The bypass bridge line BBRL2 of the second bridge line BRL2 may be electrically connected to the bypass auxiliary line BASL2 of the second auxiliary line ASL2.

In accordance with embodiments, the circuit layer 120 may further include data supply lines DSPL located in the non-display area NDA, and electrically connected between the data lines DL, and the display driving circuit 200 located in the sub-region SBA.

The data supply lines DSPL may include a first data supply line DSPL1 for transmitting the data signal of the first data line DL1, a second data supply line DSPL2 for transmitting the data signal of the second data line DL2, a third data supply line DSPL3 for transmitting the data signal of the third data line DL3, and a fourth data supply line DSPL4 for transmitting the data signal of the fourth data line DL4.

The data supply lines DSPL may extend to the remaining area of the bypass area BYPA of the display area DA except the first bypass area BYA1. That is, the data supply lines DSPL may extend to the second bypass area BYA2 and the bypass middle area BMA.

Accordingly, the third data supply line DSPL3 may extend to the third data line DL3 of the second bypass area BYA2, and may be directly electrically connected to the third data line DL3. Similarly, the fourth data supply line DSPL4 may extend to the fourth data line DL4 of the second bypass area BYA2, and may be directly electrically connected to the fourth data line DL4.

On the other hand, the first data supply line DSPL1 and the second data supply line DSPL2 may extend to the second bypass area BYA2, and thus may not be directly electrically connected to the first data line DL1 and the second data line DL2 located in the first bypass area BYA1.

In accordance with the one or more embodiments corresponding to FIG. 6, the bypass bridge line BBRL1 of the first bridge line BRL1, which is relatively adjacent to the sub-region SBA, may be electrically connected to the second data line DL2 relatively adjacent to the boundary between the first bypass area BYA1 and the second bypass area BYA2. Further, the bypass bridge line BBRL2 of the second bridge line

BRL2, which is spaced further apart from the sub-region SBA than the first bridge line BRL1, may be electrically connected to the first data line DL1 spaced further apart from the boundary between the first bypass area BYA1 and the second bypass area BYA2 than the second data line DL2.

Further, the first data supply line DSPL1 may extend to the bypass auxiliary line BASL2 of the second auxiliary line ASL2 of the second bypass area BYA2, and may be electrically connected to the first data line DL1 through the bypass auxiliary line BASL2 of the second auxiliary line ASL2 and the bypass bridge line BBRL2 of the second bridge line BRL2. Similarly, the second data supply line DSPL2 may extend to the bypass auxiliary line BASL1 of the first auxiliary line ASL1 of the second bypass area BYA2, and may be electrically connected to the second data line DL2 through the bypass auxiliary line BASL1 of the first auxiliary line ASL1 and the bypass bridge line BBRL1 of the first bridge line BRL1.

Meanwhile, the circuit layer 120 of the display device 100 according to embodiments may further include a first power supply line VDSPL and a second power supply line VSSPL extending from the sub-region SBA and located in the non-display area NDA.

The first power supply line VDSPL transmits the first power ELVDD (see FIG. 4). The first power supply line VDSPL may be located side by side with one side adjacent to the sub-region SBA among the edges of the display area DA. The second power supply line VSSPL transmits the second power ELVSS (see FIG. 4). The second power supply line VSSPL may surround the other sides except the side adjacent to the sub-region SBA among the edges of the display area DA.

Meanwhile, in accordance with embodiments, the data lines DL may further include a middle data line DLM located in the bypass middle area BMA.

Among the data supply lines DSPL, a middle data supply line DSPLM for transmitting the data signal of the middle data line DLM may extend to the middle data line DLM of the bypass middle area BMA, and may be directly electrically connected to the middle data line DLM.

The auxiliary lines ASL may further include remaining auxiliary lines RASL excluding some of the auxiliary lines located in the second bypass area BYA2. That is, the remaining auxiliary lines RASL may be located in the first bypass area BYA1 and in the bypass middle area BMA, and may extend to completely cross the display area DA.

In accordance with the one or more embodiments corresponding to FIG. 6, the first data line DL1 and the second data line DL2 located in the first bypass area BYA1, and the middle data line DLM located in the bypass middle area BMA may each be adjacent to the remaining auxiliary line RASL.

In one or more embodiments, the bridge lines BRL may further include remaining bridge lines excluding some of the bridge lines located in the bypass area BYPA of the display area DA. The remaining bridge lines may be located in the general area GA, and may extend to completely cross the display area DA.

As shown in FIG. 7, the data lines DL and the auxiliary lines BASL, AASL, and RASL (ASL in FIG. 6) may be located on the first planarization layer 125 covering the bridge lines BBRL and ABRL (BRL in FIG. 6).

For example, the bridge lines BBRL and ABRL (BRL in FIG. 6) may be located in the first source-drain conductive layer on the interlayer insulating layer 124, and may be covered with the first planarization layer 125.

The data lines DL and the auxiliary lines BASL, AASL, and RASL (ASL in FIG. 6) may be located in the second source-drain conductive layer on the first planarization layer 125.

Any one bridge line among some bridge lines BRL located in the bypass area BYPA may include the bypass bridge line BBRL extending between the first bypass area BYA1 and the second bypass area BYA2, and the additional bridge lines ABRL spaced apart from respective ends thereof.

Each of the first data line DL1 and the second data line DL2 located in the first bypass area BYA1 may be adjacent to the remaining auxiliary line RASL.

Each of some auxiliary lines ASL located in the second bypass area BYA2 may include the bypass auxiliary line BASL, and the additional auxiliary line AASL spaced apart from one end thereof.

Accordingly, each of the third data line DL3 and the fourth data line DL4 located in the second bypass area BYA2 may include a portion adjacent to the bypass auxiliary line BASL, and a portion adjacent to the additional auxiliary line AASL.

Any one bypass auxiliary line BASL among some auxiliary lines ASL located in the second bypass area BYA2 may be electrically connected to the bypass bridge line BBRL through a first bypass connection hole BYCH1 penetrating the first planarization layer 125.

The first data line DL1 or the second data line DL2 located in the first bypass area BYA1 may be electrically connected to the bypass bridge line BBRL through a second bypass connection hole BYCH2 penetrating the first planarization layer 125.

As described above, the circuit layer 120 according to embodiments includes the bridge lines BRL and the auxiliary lines ASL, so that the respective electrical connections between the first data supply line DSPL1 and the second data supply line DSPL2 and the first data line DL1 and the second data line DL2 may be implemented by the bypass auxiliary line BASL and the bypass bridge line BBRL even if the data supply lines DSPL extend only to the remaining area except the first bypass area BYA1.

Accordingly, the first data supply line DSPL1 and the second data supply line DSPL2 do not extend to the first bypass area BYA1 spaced further apart from the sub-region SBA, so that the extension lengths of the data supply lines DSPL may be reduced, thereby reducing the width of the non-display area NDA.

Further, in accordance with embodiments, each of the light-emitting pixel drivers EPD overlaps two bridge lines adjacent in the second direction DR2 among the bridge lines BRL extending in the first direction DR1. That is, when the light-emitting pixel drivers EPD are arranged in a matrix with N sub-pixel columns and M sub-pixel rows, each of the M sub-pixel rows is matched with two bridge lines BRL and, thus, 2M bridge lines BRL may be provided.

In this way, even when the display area DA of the display device 100 is relatively long in the first direction DR1, the data lines of the first bypass area BYA1 may be electrically connected to a sufficiently large number of 2M bridge lines. Therefore, even if the shape and size of the display device 100 are variously modified, a structure that electrically connects the data lines of the first bypass area BYA1 to respective data supply lines using the bridge lines BRL and the auxiliary lines ASL may be applied, which makes it possible to reduce the width of the non-display area NDA. Further, the bypass auxiliary lines BASL of some auxiliary lines ASL arranged in the bypass area BYPA are located between the data supply lines DSPL of the non-display area NDA and the bypass bridge lines BBRL of the bridge lines BRL. Therefore, as in embodiments, each of the M sub-pixel rows is matched with two bridge lines BRL, so that the extension lengths of the bypass auxiliary lines BASL of some auxiliary lines ASL arranged in the bypass area BYPA may be reduced.

Therefore, the resistance of the signal transmission paths between the display driving circuit 200 and the data lines DL may be reduced, so that the power consumption of the display device 100 may be lowered and the delay or distortion of the data signal may be reduced.

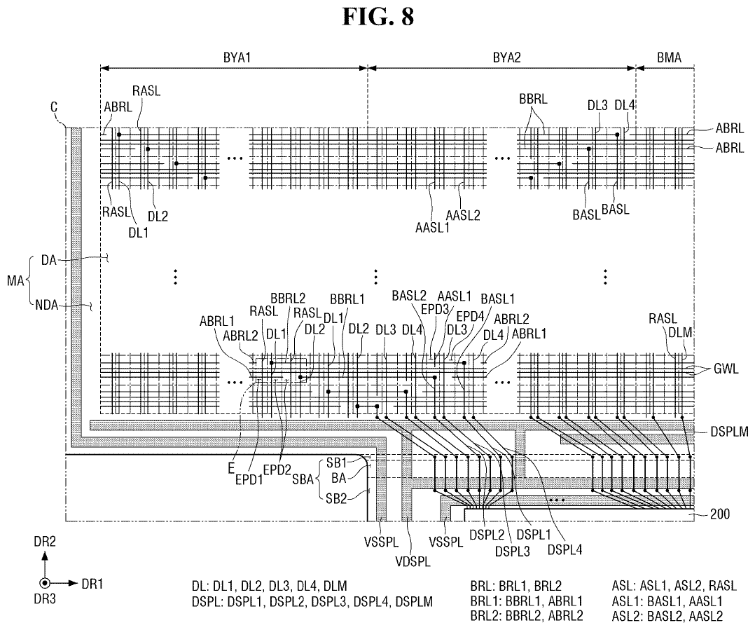

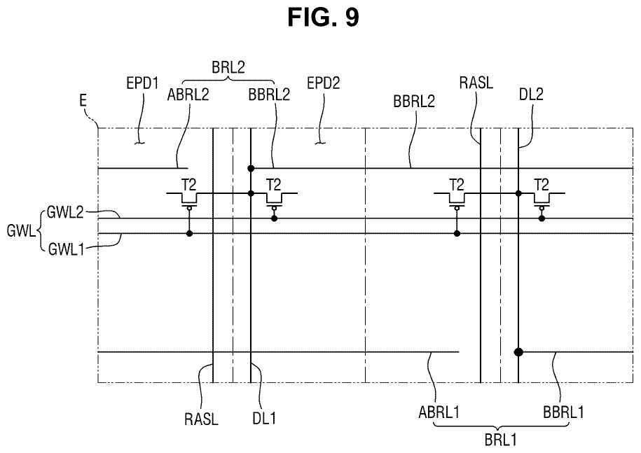

FIG. 8 is a layout diagram showing part C of FIG. 1 according to one or more embodiments. FIG. 9 is a layout diagram illustrating part E of FIG. 8.

The display device 100 according to the one or more embodiments corresponding to FIGS. 8 and 9 is substantially the same as the one or more embodiments corresponding to FIG. 6 except that two light-emitting pixel drivers EPD adjacent in the first direction DR1 among the light-emitting pixel drivers EPD share one data line DL, so that redundant description will be omitted below.

As shown in FIG. 8, the circuit layer 120 according to one or more embodiments may include the scan write lines GWL for transmitting the scan write signal GW (see FIG. 5) to the light-emitting pixel drivers EPD. The scan write lines GWL may extend in the first direction DR1.

In accordance with the one or more embodiments corresponding to FIG. 8, each of the light-emitting pixel drivers EPD may overlap two scan write lines GWL that are adjacent in the second direction DR2 among the scan write lines GWL. Further, among the light-emitting pixel drivers EPD, two light-emitting pixel drivers EPD adjacent in the first direction DR1 and electrically connected to one data line may be electrically connected to different scan write lines GWL.

As shown in FIG. 9, the scan write lines GWL may include a first scan write line GWL1 and a second scan write line GWL2 adjacent to each other in the second direction DR2 and overlapping the first light-emitting pixel driver EPD1 and the second light-emitting pixel driver EPD2 adjacent to each other in the first direction DR1.

The first light-emitting pixel driver EPD1 and the second light-emitting pixel driver EPD2 adjacent to each other in the first direction DR1 may be electrically connected to the first data line DL1. The first light-emitting pixel driver EPD1 may be electrically connected to the first scan write line GWL1. The second light-emitting pixel driver EPD2 may be electrically connected to the second scan write line GWL2.

That is, the second transistor T2 of each of the first light-emitting pixel driver EPD1 and the second light-emitting pixel driver EPD2 may be electrically connected to the first data line DL. Further, the second transistor T2 of the first light-emitting pixel driver EPD1 may be turned on by the scan write signal of the first scan write line GWL1, and the second transistor T2 of the second light-emitting pixel driver EPD2 may be turned on by the scan write signal of the second scan write line GWL2.

Therefore, by supplying the scan write signal to the first scan write line GWL1 and to the second scan write line GWL2 for different periods, time division may be performed on the data signal of the first data line DL. In this way, by using the first scan write line GWL1 and the second scan write line GWL2, one first data line DL1 may be shared to transmit the data signal of the first light-emitting pixel driver EPD1 and the data signal of the second light-emitting pixel driver EPD2.

Similarly, the third data line DL3 of the second bypass area BYA2 may be electrically connected to the third light-emitting pixel driver EPD3 and to the fourth light-emitting pixel driver EPD4 adjacent in the first direction DR1. The third light-emitting pixel driver EPD3 may be electrically connected to the first scan write line GWL1. The fourth light-emitting pixel driver EPD4 may be electrically connected to the second scan write line GWL2.

As shown in FIG. 8, the first auxiliary line ASL1 may be adjacent to the third data line DL3. The second auxiliary line ASL2 may be adjacent to the fourth data line DL4.

In accordance with one or more embodiments, for symmetry of the light-emitting pixel drivers EPD, one of two light-emitting pixel drivers EPD adjacent in the first direction DR1 may overlap the auxiliary line ASL, and the other one may overlap the data line DL. For example, among the first light-emitting pixel driver EPD1 and the second light-emitting pixel driver EPD2 adjacent in the first direction DR1, the first light-emitting pixel driver EPD1 may overlap the remaining auxiliary line RASL, and the second light-emitting pixel driver EPD2 may overlap the first data line DL1. Similarly, among the third light-emitting pixel driver EPD3 and the fourth light-emitting pixel driver EPD4 adjacent in the first direction DR1, the third light-emitting pixel driver EPD3 may overlap the first auxiliary line ASL1, and the fourth light-emitting pixel driver EPD4 may overlap the third data line DL3.

In this way, in accordance with one or more embodiments, the light-emitting pixel drivers adjacent in the first direction DR1 may share one data line. Therefore, when the light-emitting pixel drivers EPD are arranged in a matrix with N sub-pixel columns and M sub-pixel rows, the number of data lines DL may be reduced to N/2 rather than N. Therefore, as the number of data lines DL decreases, the number of data supply lines DSPL also decreases, thereby reducing the width of the non-display area NDA. Further, because the number of data lines of the first bypass area BYA1 may also be reduced, it may be easier to apply a structure that electrically connects the data lines of the first bypass area BYA1 to the respective data supply lines using the bridge lines BRL and the auxiliary lines ASL, even if the shape and size of the display device 100 are variously modified.

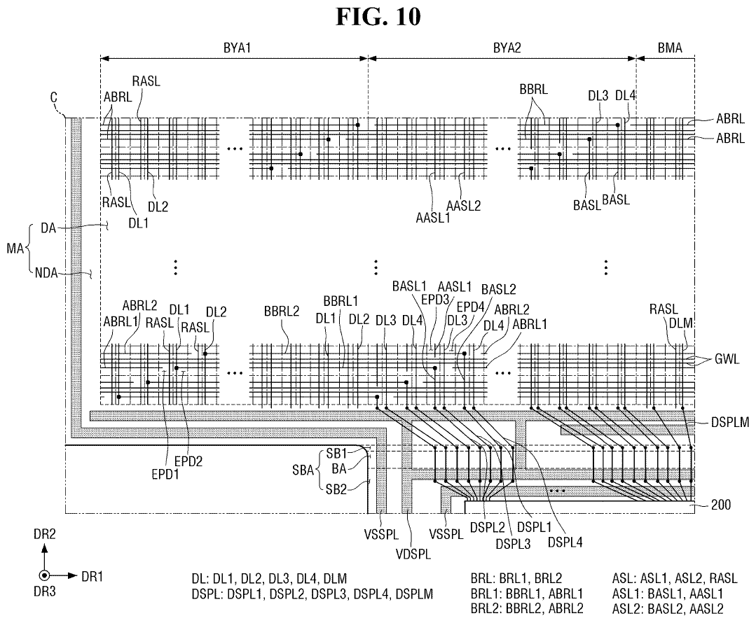

FIG. 10 is a layout diagram showing part C of FIG. 1 according to one or more embodiments.

The display device 100 according to the one or more embodiments corresponding to FIG. 10 is substantially the same as the display device of the one or more embodiments corresponding to FIGS. 8 and 9, except that the data line adjacent to the non-display area NDA among the data lines DL1 and DL2 of the first bypass area BYA1 is electrically connected to the bypass auxiliary line BASL adjacent to the boundary between the first bypass area BYA1 and the second bypass area BYA2 among the bypass auxiliary lines BASL of the auxiliary lines ASL of the second bypass area BYA2, so that redundant description will be omitted below.

In accordance with the one or more embodiments corresponding to FIG. 10, the bridge lines BRL include the first bridge line BRL1 and the second bridge line BRL2 overlapping the first light-emitting pixel driver EPD1, the second light-emitting pixel driver EPD2, the third light-emitting pixel driver EPD3, and the fourth light-emitting pixel driver EPD4, which are arranged side by side in the first direction DR1.

The first bridge line BRL1 may be closer to the sub-region SBA than the second bridge line BRL2 in the second direction DR2. That is, the second bridge line BRL2 may be spaced further apart from the sub-region SBA than the first bridge line BRL1 in the second direction DR2. In other words, the first bridge line BRL1 may be located between the sub-region SBA and the second bridge line BRL2 in the second direction DR2.

The first bridge line BRL1 and the second bridge line BRL2 may respectively include the bypass bridge lines BBRL1 and BBRL2 and two additional bridge lines ABRL1 and ABRL2 extending from/from near respective ends of the respective one of the bypass bridge lines BBRL1 and BBRL2 to the non-display area NDA, respectively.

In accordance with one or more embodiments, the auxiliary lines ASL include the first auxiliary line ASL1 and the second auxiliary line ASL2 located in the second bypass area BYA2. The first auxiliary line ASL1 may be adjacent to one side of the third data line DL3 in the first direction DR1. The second auxiliary line ASL2 may be adjacent to one side of the fourth data line DL4 in the first direction DR1.

The first auxiliary line ASL1 may be closer to the first bypass area BYA1 than the third data line DL3 and the second auxiliary line ASL2 in the second direction DR2. That is, the first auxiliary line ASL1 may be located between the first bypass area BYA1 and the third data line DL3 in the second direction DR2.

The first auxiliary line ASL1 and the second auxiliary line ASL2 may respectively include the bypass auxiliary lines BASL1 and BASL2 extending from one side adjacent to the sub-region SBA among the edges of the display area DA, and the additional auxiliary lines AASL1 and AASL2 extending from another side opposite to the sub-region SBA among the edges of the display area DA to one ends of the bypass auxiliary lines BASL1 and BASL2, respectively.

The data lines DL may include the first data line DL1 and the second data line DL2 located in the first bypass area BYA1 and adjacent to each other in the first direction DR1. The first data line DL1 may be closer to the non-display area NDA than the second data line DL2 in the first direction DR1. That is, the first data line DL1 may be located between the non-display area NDA and the second data line DL2 in the first direction DR1.

In other words, the second data line DL2 may be closer to the second bypass area BYA2 than the first data line DL1 in the first direction DR1. That is, the second data line DL2 may be located between the first data line DL1 and the second bypass area BYA2 in the first direction DR1.

In accordance with the one or more embodiments corresponding to FIG. 10, the bypass bridge line BBRL1 of the first bridge line BRL1 relatively adjacent to the sub-region SBA in the second direction DR2 may be electrically connected between the first data line DL1 relatively adjacent to the non-display area NDA in the first direction DR1 and the bypass auxiliary line BASL1 of the first auxiliary line ASL1 relatively adjacent to the first bypass area BYA1 in the first direction DR1. Further, the bypass bridge line BBRL2 of the second bridge line BRL2 may be electrically connected between the second data line DL2 and the bypass auxiliary line BASL2 of the second auxiliary line ASL2.

In this way, the extension lengths of the bypass bridge lines BBRL of the bridge lines BRL located in the bypass area BYPA may become similar to each other. Accordingly, the difference in the signal transmission paths between the data lines DL1 and DL2 arranged in the first bypass area BYA1 and the corresponding data supply lines DSPL1 and DSPL2 may be derived only by the extension lengths of the bypass auxiliary lines BASL of the auxiliary line ASL located in the second bypass area BYA2. Therefore, the difference in the signal transmission paths between the data lines DL1 and DL2 arranged in the first bypass area BYA1 and the corresponding data supply lines DSPL1 and DSPL2 may be more easily compensated for.

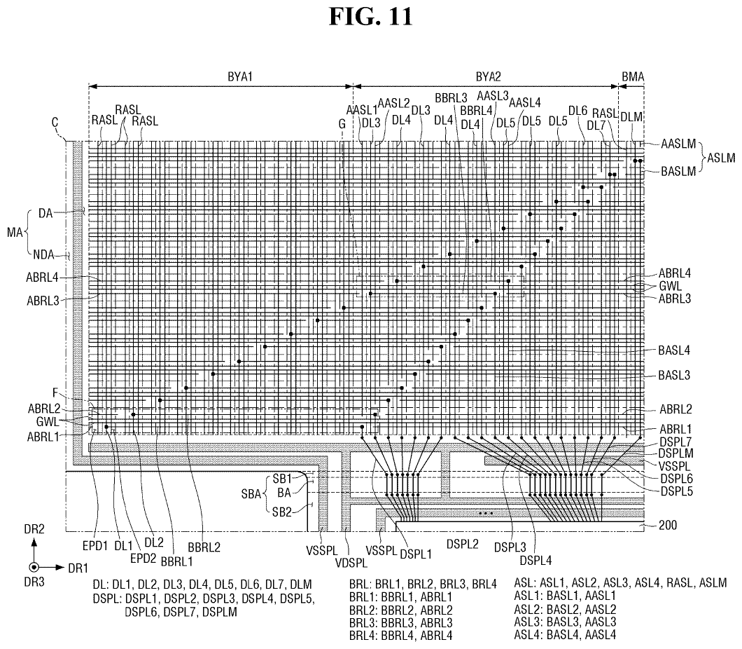

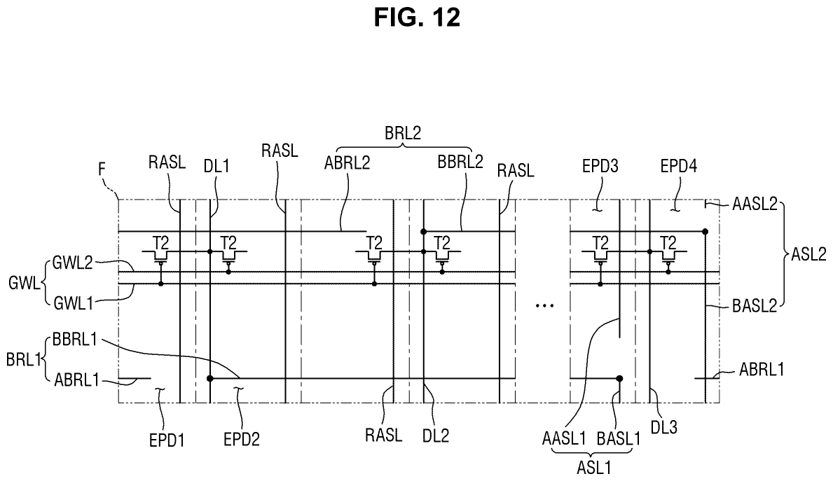

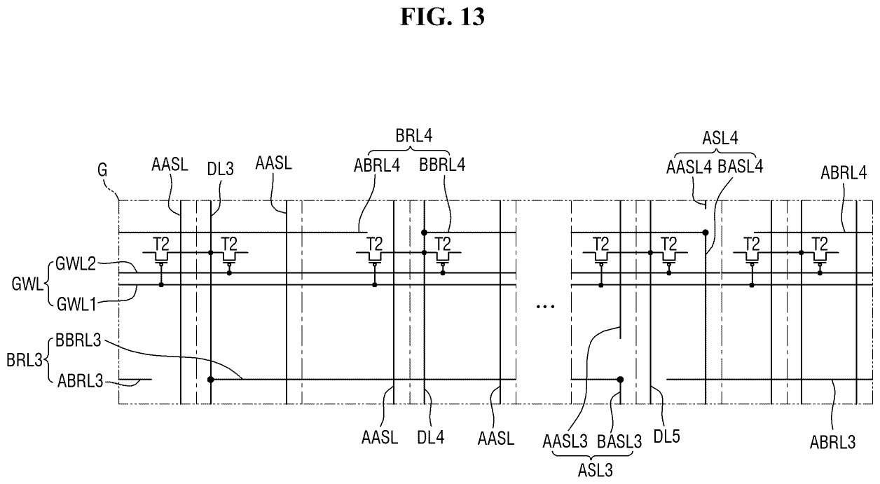

FIG. 11 is a layout diagram showing part C of FIG. 1 according to one or more embodiments. FIG. 12 is a layout diagram illustrating part F of FIG. 11. FIG. 13 is a layout diagram illustrating part G of FIG. 11.

The display device 100 according to the one or more embodiments corresponding to FIG. 11 is substantially the same as the display device of the one or more embodiments corresponding to FIG. 10, except that two auxiliary lines ASL are arranged between two data lines DL adjacent to each other in the first direction DR1, and except that the data lines DL3 and DL4 of the second bypass area BYA2 are electrically connected to the respective data supply lines DSPL3 and DSPL4 through the bypass auxiliary line BASL and the bypass bridge line BBRL located in the second bypass area BYA2, so that redundant description will be omitted below.

Referring to FIGS. 11 and 12, the light-emitting pixel drivers EPD may include the first light-emitting pixel driver EPD1 located in the first bypass area BYA1, the second light-emitting pixel driver EPD2 adjacent to the first light-emitting pixel driver EPD1 in the first direction DR1, the third light-emitting pixel driver EPD3 located in the second bypass area BYA2 to be arranged side by side with the first light-emitting pixel driver EPD1 in the first direction DR1 and spaced apart from the first light-emitting pixel driver EPD1, and the fourth light-emitting pixel driver EPD4 adjacent to the third light-emitting pixel driver EPD3 in the first direction DR1.

The scan write lines GWL may overlap the first light-emitting pixel driver EPD1, the second light-emitting pixel driver EPD2, the third light-emitting pixel driver EPD3, and the fourth light-emitting pixel driver EPD4, and may include the first scan write line GWL1 and the second scan write line GWL2 adjacent to each other in the second direction DR2.

The first light-emitting pixel driver EPD1 and the third light-emitting pixel driver EPD3 may be electrically connected to the first scan write line GWL1. That is, the second transistor T2 of each of the first light-emitting pixel driver EPD1 and the third light-emitting pixel driver EPD3 may be turned on by the scan write signal GW of the first scan write line GWL1. The second light-emitting pixel driver EPD2 and the fourth light-emitting pixel driver EPD4 may be electrically connected to the second scan write line GWL2. That is, the second transistor T2 of each of the second light-emitting pixel driver EPD2 and the fourth light-emitting pixel driver EPD4 may be turned on by the scan write signal GW of the second scan write line GWL2.

The data lines DL may include the first data line DL1 and the second data line DL2 located in the first bypass area BYA1, and the third data line DL3 and the fourth data line DL4 located in a portion of the second bypass area BYA2 that is contacting the first bypass area BYA1. The first data line DL1 and the second data line DL2 may be located adjacent to each other in the first direction DR1. The first data line DL1 may be closer to the non-display area NDA than the second data line DL2. The third data line DL3 and the fourth data line DL4 may be located adjacent to each other in the first direction DR1. The third data line DL3 may be closer to the first bypass area BYA1 than the fourth data line DL4.

The first data line DL1 may be electrically connected to the first light-emitting pixel driver EPD1 and the second light-emitting pixel driver EPD2. That is, the second transistor T2 of each of the first light-emitting pixel driver EPD1 and the second light-emitting pixel driver EPD2 may be electrically connected to the first data line DL1. The third data line DL3 may be electrically connected to the third light-emitting pixel driver EPD3 and the fourth light-emitting pixel driver EPD4. That is, the second transistor T2 of each of the third light-emitting pixel driver EPD3 and the fourth light-emitting pixel driver EPD4 may be electrically connected to the third data line DL3.

The first data line DL1 may overlap one of the first light-emitting pixel driver EPD1 and the second light-emitting pixel driver EPD2. Alternatively, the first data line DL1 may overlap the boundary between the first light-emitting pixel driver EPD1 and the second light-emitting pixel driver EPD2. The third data line DL3 may overlap one of the third light-emitting pixel driver EPD3 and the fourth light-emitting pixel driver EPD4. Alternatively, the third data line DL3 may overlap the boundary between the third light-emitting pixel driver EPD3 and the fourth light-emitting pixel driver EPD4.

The bridge lines BRL may overlap the first light-emitting pixel driver EPD1, and the second light-emitting pixel driver EPD2, the third light-emitting pixel driver EPD3, and the fourth light-emitting pixel driver EPD4 that are arranged side by side with the first light-emitting pixel driver EPD1 in the first direction DR1, and may include the first bridge line BRL1 and the second bridge line BRL2 adjacent to each other in the second direction DR2. The first bridge line BRL1 may be closer to the sub-region SBA than the second bridge line BRL2 in the second direction DR2. The first bridge line BRL1 and the second bridge line BRL2 may include the bypass bridge lines BBRL1 and BBRL2 extending between the first bypass area BYA1 and the second bypass area BYA2, respectively.

As shown in FIG. 11, in addition to the first bridge line BRL1 and the second bridge line BRL2, each of the bridge lines BRL located in the first bypass area BYA1 and the second bypass area BYA2 may include the bypass bridge line BBRL extending between the first bypass area BYA1 and the second bypass area BYA2. Further, each of the bridge lines BRL located in the first bypass area BYA1 and the second bypass area BYA2 may further include two additional bridge lines ABRL extending from/from near respective ends of the bypass bridge line BBRL to the non-display area NDA.

As shown in FIG. 11, two auxiliary lines ASL adjacent to each other in the first direction DR1 may be located between two data lines DL adjacent in the first direction DR1. Accordingly, each of the data lines DL may be matched with two auxiliary lines ASL adjacent on respective sides thereof in the first direction DR1. For example, the first data line DL1 may be adjacent to two remaining auxiliary lines RASL on respective sides in the first direction DR1.

For another example, the third data line DL3 may be adjacent to the first auxiliary line ASL1 on one side in the first direction DR1, and may be adjacent to the second auxiliary line ASL2 on the other side in the first direction DR1. That is, the third data line DL3 may be located between the first auxiliary line ASL1 and the second auxiliary line ASL2 in the first direction DR1. The first auxiliary line ASL1 may be closer to the first bypass area BYA1 than the third data line DL3 and the second auxiliary line ASL2 in the second direction DR2.

The first auxiliary line ASL1 and the second auxiliary line ASL2 may include the bypass auxiliary line BASL1 and the bypass auxiliary line BASL2 located in the second bypass area BYA2, respectively.

The bypass bridge line BBRL1 of the first bridge line BRL1 may be electrically connected between the first data line DL1 and the bypass auxiliary line BASL1 of the first auxiliary line ASL1. The bypass bridge line BBRL2 of the second bridge line BRL2 may be electrically connected between the second data line DL2 and the bypass auxiliary line BASL2 of the second auxiliary line ASL2.

The first data supply line DSPL1 extends to the bypass auxiliary line BASL1 of the first auxiliary line ASL1 located in the second bypass area BYA2, and thus may be electrically connected to the first data line DL1 through the bypass auxiliary line BASL1 of the first auxiliary line ASL1 and the bypass bridge line BBRL1 of the first bridge line BRL1. The second data supply line DSPL2 extends to the bypass auxiliary line BASL2 of the second auxiliary line ASL2 located in the second bypass area BYA2, and thus may be electrically connected to the second data line DL2 through the bypass auxiliary line BASL2 of the second auxiliary line ASL2 and the bypass bridge line BBRL2 of the second bridge line BRL2.

In this way, in accordance with the one or more embodiments corresponding to FIG. 11, among the data lines DL1 and DL2 of the first bypass area BYA1, the data line DL1 relatively adjacent to the non-display area NDA may be electrically connected to the corresponding data supply line DSPL1 through the bypass bridge line BBRL relatively adjacent to the sub-region SBA, and through the bypass auxiliary line BASL relatively adjacent to the boundary between the first bypass area BYA1 and the second bypass area BYA2.

Further, in accordance with the one or more embodiments corresponding to FIG. 11, the data lines DL may further include a fifth data line DL5 located in the second bypass area BYA2, and spaced further apart from the first data line DL1 than the third data line DL3 in the first direction DR1. That is, the fifth data line DL5 may be located in a portion of the second bypass area BYA2 that is spaced further apart from the first bypass area BYA1.

The auxiliary lines ASL may further include a third auxiliary line ASL3 adjacent to the fifth data line DL5 on one side in the first direction DR1, and a fourth auxiliary line ASL4 adjacent to the fifth data line DL5 on the other side in the first direction DR1.

The fourth auxiliary line ASL4 may be spaced further apart from the first bypass area BYA1 than the third auxiliary line ASL3 in the first direction DR1. The third auxiliary line ASL3 and the fourth auxiliary line ASL4 may include bypass auxiliary lines BASL3 and BASL4 and additional auxiliary lines AASL3 and AASL4, respectively.

The bridge lines BRL may further include a third bridge line BRL3 and a fourth bridge line BRL4 that are adjacent to each other, and spaced further apart from the sub-region SBA than the second bridge line BRL2 in the second direction DR2, and may overlap the first bypass area BYA1 and the second bypass area BYA2. The fourth bridge line BRL4 may be spaced further apart from the sub-region SBA than the third bridge line BRL3 in the second direction DR2.

The third bridge line BRL3 and the fourth bridge line BRL4 may include bypass bridge lines BBRL3 and BBRL4 and two additional bridge lines ABRL3 and ABRL4 extending from respective ends thereof to the non-display area NDA, respectively.

Referring to FIGS. 11 and 13, the third data line DL3 located in a portion of the second bypass area BYA2 adjacent to the first bypass area BYA1 may not be directly connected to the third data supply line DSPL3, but may be electrically connected to the third data supply line DSPL3 through the bypass auxiliary line BASL3 of the third auxiliary line ASL3 and through the bypass bridge line BBRL3 of the third bridge line BRL3. Similarly, the fourth data line DL4 may be electrically connected to the fourth data supply line DSPL4 through the bypass auxiliary line BASL4 of the fourth auxiliary line ASL4 and through the bypass bridge line BBRL4 of the fourth bridge line BRL4.

The fifth data line DL5 may be electrically connected to the fifth data supply line DSPL5 through the bypass auxiliary line BASL of the auxiliary line ASL forming a pair with a sixth data line DL6 spaced further apart from the boundary between the first bypass area BYA1 and the second bypass area BYA2 than the fifth data line DL5.

The sixth data line DL6 may be electrically connected to the sixth data supply line DSPL6 through the bypass auxiliary line BASL of the auxiliary line forming a pair with a seventh data line DL7 spaced further apart from the boundary between the first bypass area BYA1 and the second bypass area BYA2 than the sixth data line DL6.

The seventh data line DL7 may be spaced farthest from the boundary between the first bypass area BYA1 and the second bypass area BYA2 among the data lines DL3, DL4, DL5, DL6, and DL7 of the second bypass area BYA2, and may be electrically connected to the seventh data supply line DSPL7 through the bypass auxiliary line BASL of the auxiliary line forming a pair therewith.

Further, in accordance with the one or more embodiments corresponding to FIG. 11, one of two auxiliary lines ASL adjacent to the middle data line DLM of the bypass middle area BMA on respective sides in the first direction DR1 may be a middle auxiliary line ASLM including a bypass auxiliary line BASLM and an additional auxiliary line AASLM, and the other one may be the remaining auxiliary line RASL.

The middle data line DLM may not be directly electrically connected to the middle data supply line DSPLM, but may be electrically connected to the middle data supply line DSPLM through the bypass bridge line and the bypass auxiliary line BASLM of the middle auxiliary line ASLM.

In this way, in accordance with the one or more embodiments corresponding to FIG. 11, some of the data lines DL are not directly electrically connected to the corresponding data supply line DSPL, but all the data lines DL are electrically connected to the corresponding data supply line DSPL through the bypass bridge line BBRL and the bypass auxiliary line BASL.

Further, when the light-emitting pixel drivers EPD are arranged in a matrix with N sub-pixel columns and M sub-pixel rows, each of the M sub-pixel rows is matched with two bridge lines BRL, so that 2M bridge lines BRL may be provided. Further, because each of the N sub-pixel columns is matched with two auxiliary lines ASL, 2N auxiliary lines ASL may be provided.

Further, the data lines DL of the first bypass area BYA1 and the second bypass area BYA2, which are closer to the non-display area NDA adjacent to the first bypass area BYA1, may be matched with the bridge line BRL adjacent to the sub-region SBA and the auxiliary line ASL adjacent to the boundary between the first bypass area BYA1 and the second bypass area BYA2.

Accordingly, the bypass bridge lines BBRL of the bridge lines BRL of the first bypass area BYA1 and the second bypass area BYA2 may be arranged with extension lengths that gradually increase as they are closer to the sub-region SBA.

Further, the bypass auxiliary lines BASL of the auxiliary lines ASL of the second bypass area BYA2 may be arranged with extension lengths that gradually decrease as they are closer to the boundary between the first bypass area BYA1 and the second bypass area BYA2.

That is, the extension length of the bypass bridge line BBRL1 of the first bridge line BRL1 may be longer than the extension length of the bypass bridge line BBRL2 of the second bridge line BRL2, the extension length of the bypass bridge line BBRL2 of the second bridge line BRL2 may be longer than the extension length of the bypass bridge line BBRL3 of the third bridge line BRL3, and the extension length of the bypass bridge line BBRL3 of the third bridge line BRL3 may be longer than the extension length of the bypass bridge line BBRL4 of the fourth bridge line BRL4.

Further, the extension length of the bypass auxiliary line BASL1 of the first auxiliary line ASL1 may be shorter than the extension length of the bypass auxiliary line BASL2 of the second auxiliary line ASL2, the extension length of the bypass auxiliary line BASL2 of the second auxiliary line ASL2 may be shorter than the extension length of the bypass auxiliary line BASL3 of the third auxiliary line ASL3, and the extension length of the bypass auxiliary line BASL3 of the third auxiliary line ASL3 may be shorter than the extension length of the bypass auxiliary line BASL4 of the fourth auxiliary line ASL4.

Accordingly, the data lines DL of the first bypass area BYA1 and the second bypass area BYA2 are respectively electrically connected to the data supply lines DSPL through the bypass bridge lines BBRL and the bypass auxiliary lines BASL, so that the signal transmission paths between the data lines DL and the data supply lines DSPL of the first bypass area BYA1 and the second bypass area BYA2 may have similar extension lengths.

Therefore, the variation in delay or distortion of the data signal Vdata applied to the data lines DL may be reduced, thereby more easily compensating for the delay or distortion of the data signal Vdata applied to the data lines DL.

However, the aspects of the present disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A display device comprising:
a substrate comprising a display area having emission areas, a circuit layer above the substrate, and an element layer above the circuit layer and comprising light-emitting elements respectively in the emission areas,
wherein the circuit layer comprises:
light-emitting pixel drivers respectively electrically connected to the light-emitting elements, and arranged in a first direction and in a second direction;
data lines extending in the second direction for transmitting a data signal to the light-emitting pixel drivers;
bridge lines extending in the first direction, and comprising a first bridge line and a second bridge line overlapping a first light-emitting pixel driver among the light-emitting pixel drivers; and
auxiliary lines extending in the second direction adjacent to the data lines.

2. The display device of claim 1, wherein the first bridge line and the second bridge line further overlap a second light-emitting pixel driver among the light-emitting pixel drivers that is adjacent to the first light-emitting pixel driver in the first direction.

3. The display device of claim 2, wherein the substrate comprises:
a main region comprising the display area, and a non-display area around the display area; and
a sub-region at one side of the main region,
wherein the display area comprises a first bypass area contacting the non-display area in the first direction, and a second bypass area contacting the first bypass area in the first direction, and adjacent to the sub-region in the second direction,
wherein the data lines comprise a first data line and a second data line adjacent to each other in the first direction in the first bypass area, and a third data line and a fourth data line adjacent to each other in the first direction in the second bypass area,
wherein the first light-emitting pixel driver and the second light-emitting pixel driver are in the first bypass area,
wherein the light-emitting pixel drivers comprise a third light-emitting pixel driver in the second bypass area and spaced apart from the first light-emitting pixel driver, and a fourth light-emitting pixel driver adjacent to the third light-emitting pixel driver in the first direction,
wherein the first data line is electrically connected to at least one of the first light-emitting pixel driver or the second light-emitting pixel driver,
wherein the third data line is electrically connected to at least one of the third light-emitting pixel driver or the fourth light-emitting pixel driver, and wherein the first bridge line and the second bridge line further overlap the third light-emitting pixel driver and the fourth light-emitting pixel driver.

4. The display device of claim 3, wherein the auxiliary lines comprise a first auxiliary line overlapping the third light-emitting pixel driver, and a second auxiliary line adjacent to the first auxiliary line in the first direction,
wherein the first bridge line comprises a first bypass bridge line spaced apart from an edge of the display area,
wherein the second bridge line comprises a second bypass bridge line spaced apart from the edge of the display area,
wherein the first auxiliary line comprises a first bypass auxiliary line electrically connected to the first bypass bridge line, and extending from one of the edges of the display area,
wherein the second auxiliary line comprises a second bypass auxiliary line electrically connected to the second bypass bridge line and extending from the one of the edges of the display area.

5. The display device of claim 4, wherein the first bridge line further comprises two first additional bridge lines respectively between the first bypass bridge line and two opposing edges of the display area in the first direction,
wherein the second bridge line further comprises two second additional bridge lines respectively between the second bypass bridge line and the two opposing edges of the display area in the first direction,
wherein the first auxiliary line further comprises a first additional auxiliary line between the first bypass auxiliary line and another edge of the display area in the second direction, and
wherein the second auxiliary line further comprises a second additional auxiliary line between the second bypass auxiliary line and the another edge of the display area in the second direction.

6. The display device of claim 4, wherein the circuit layer further comprises data supply lines in the non-display area, respectively electrically connected between the data lines and a display driving circuit in the sub-region, and comprising:
a first data supply line for transmitting the data signal of the first data line;
a second data supply line for transmitting the data signal of the second data line;
a third data supply line for transmitting the data signal of the third data line; and
a fourth data supply line for transmitting the data signal of the fourth data line.

7. The display device of claim 6, wherein the first bypass bridge line is electrically connected to the second data line,
wherein the second bypass bridge line is electrically connected to the first data line,
wherein the first data supply line is electrically connected to the first data line through the second bypass auxiliary line and the second bypass bridge line,
wherein the second data supply line is electrically connected to the second data line through the first bypass auxiliary line and the first bypass bridge line,
wherein the third data supply line extends to the third data line to be electrically connected to the third data line, and
wherein the fourth data supply line extends to the fourth data line to be electrically connected to the fourth data line.

8. The display device of claim 7, wherein the first data line is electrically connected to the first light-emitting pixel driver,
wherein the second data line is electrically connected to the second light-emitting pixel driver,
wherein the third data line is electrically connected to the third light-emitting pixel driver, and
wherein the fourth data line is electrically connected to the fourth light-emitting pixel driver.

9. The display device of claim 6, wherein the circuit layer further comprises scan write lines extending in the first direction for transmitting a scan write signal to the light-emitting pixel drivers, and comprising a first scan write line and a second scan write line that are adjacent to each other in the second direction and that overlap the first light-emitting pixel driver, the second light-emitting pixel driver, the third light-emitting pixel driver, and the fourth light-emitting pixel driver,
wherein the first data line is electrically connected to the first light-emitting pixel driver and the second light-emitting pixel driver,
wherein the third data line is electrically connected to the third light-emitting pixel driver and the fourth light-emitting pixel driver,
wherein the first light-emitting pixel driver and the third light-emitting pixel driver are electrically connected to the first scan write line, and
wherein the second light-emitting pixel driver and the fourth light-emitting pixel driver are electrically connected to the second scan write line.

10. The display device of claim 9, wherein the light-emitting pixel drivers comprise:
a first transistor electrically connected between a first node electrically connected to a first electrode of the first transistor and a second node electrically connected to a second electrode of the first transistor;
a pixel capacitor electrically connected between a first power line for transmitting a first power and a third node electrically connected to a gate electrode of the first transistor; and
a second transistor electrically connected between a corresponding one of the data lines and the first node,
wherein the second transistor of the first light-emitting pixel driver and the third light-emitting pixel driver is electrically connected to the first scan write line, and
the second transistor of the second light-emitting pixel driver and the fourth light-emitting pixel driver is electrically connected to the second scan write line.

11. The display device of claim 9, wherein the first auxiliary line is adjacent to the third data line on one side in the first direction, and
wherein the second auxiliary line is adjacent to the fourth data line on one side in the first direction.

12. The display device of claim 11, wherein the first bypass bridge line is electrically connected to the second data line,
wherein the second bypass bridge line is electrically connected to the first data line,
wherein the first data supply line is electrically connected to the first data line through the second bypass auxiliary line and the second bypass bridge line,
wherein the second data supply line is electrically connected to the second data line through the first bypass auxiliary line and the first bypass bridge line,
wherein the third data supply line extends to the third data line to be electrically connected to the third data line, and
the fourth data supply line extends to the fourth data line to be electrically connected to the fourth data line.

13. The display device of claim 11, wherein the first bypass bridge line is electrically connected to the first data line,
wherein the second bypass bridge line is electrically connected to the second data line,
wherein the first data supply line is electrically connected to the first data line through the first bypass auxiliary line and the first bypass bridge line,
wherein the second data supply line is electrically connected to the second data line through the second bypass auxiliary line and the second bypass bridge line,
wherein the third data supply line extends to the third data line to be directly electrically connected to the third data line, and
wherein the fourth data supply line extends to the fourth data line to be directly electrically connected to the fourth data line.

14. The display device of claim 9, wherein two of the auxiliary lines adjacent in the first direction are between two of the data lines adjacent in the first direction,
wherein the first auxiliary line is adjacent to the third data line on one side in the first direction, and
wherein the second auxiliary line is adjacent to the third data line on another side in the first direction.

15. The display device of claim 14, wherein the first bypass bridge line is electrically connected to the first data line,
wherein the second bypass bridge line is electrically connected to the second data line,
wherein the first data supply line is electrically connected to the first data line through the first bypass auxiliary line and the first bypass bridge line, and
wherein the second data supply line is electrically connected to the second data line through the second bypass auxiliary line and the second bypass bridge line.

16. The display device of claim 15, wherein the data lines further comprise a fifth data line in the second bypass area and spaced further from the first data line than the third data line in the first direction,
wherein the auxiliary lines further comprise a third auxiliary line adjacent to the fifth data line on one side in the first direction, and a fourth auxiliary line adjacent to the fifth data line on another side in the first direction,
wherein the third auxiliary line comprises a third bypass auxiliary line extending from the one of the edges of the display area,
wherein the fourth auxiliary line comprises a fourth bypass auxiliary line extending from the one of the edges of the display area,
wherein the bridge lines further comprise a third bridge line and a fourth bridge line that are adjacent to each other, that are spaced further from the sub-region than
the second bridge line in the second direction, and that overlap the first bypass area and the second bypass area,
wherein the third bridge line comprises a third bypass bridge line spaced apart from the edge of the display area,
wherein the fourth bridge line comprises a fourth bypass bridge line spaced apart from the edge of the display area,
wherein the third bypass bridge line is electrically connected between the third data line and the third bypass auxiliary line,
wherein the fourth bypass bridge line is electrically connected between the fourth data line and the fourth bypass auxiliary line,
wherein the third data supply line is electrically connected to the third data line through the third bypass auxiliary line and the third bypass bridge line, and
wherein the fourth data supply line is electrically connected to the fourth data line through the fourth bypass auxiliary line and the fourth bypass bridge line.

17. The display device of claim 16, wherein an extension length of the first bypass bridge line is greater than an extension length of the second bypass bridge line, which is greater than an extension length of the third bypass bridge line, which is in turn greater than an extension length of the fourth bypass bridge line.

18. The display device of claim 17, wherein an extension length of the first bypass auxiliary line is less than an extension length of the second bypass auxiliary line, which is less than an extension length of the third bypass auxiliary line, which is in turn less than an extension length of the fourth bypass auxiliary line.

19. A display device comprising:
a substrate comprising a display area having emission areas, a circuit layer above the substrate, and an element layer above the circuit layer and comprising light-emitting elements respectively in the emission areas,
wherein the circuit layer comprises:
light-emitting pixel drivers respectively electrically connected to the light-emitting elements, and arranged in a first direction and in a second direction;
scan write lines extending in the first direction for transmitting a scan write signal to the light-emitting pixel drivers;
data lines extending in the second direction for transmitting a data signal to the light-emitting pixel drivers;
bridge lines extending in the first direction; and
auxiliary lines extending in the second direction adjacent to the data lines,
wherein a first light-emitting pixel driver among the light-emitting pixel drivers is electrically connected to one of the data lines and to a first scan write line among the scan write lines,
wherein a second light-emitting pixel driver among the light-emitting pixel drivers adjacent to the first light-emitting pixel driver in the first direction is electrically connected to the one of the data lines and to a second scan write line among the scan write lines adjacent to the first scan write line,
wherein the light-emitting pixel drivers overlap two of the bridge lines that are adjacent in the second direction, and
wherein two auxiliary lines are arranged on one side of each of the data lines in the first direction.

20. The display device of claim 19, wherein the substrate comprises a main region comprising the display area and a non-display area around the display area, and a sub-region protruding from one side of the main region,
wherein the display area comprises a first bypass area contacting the non-display area in the first direction, and a second bypass area contacting the first bypass area in the first direction and adjacent to the sub-region in the second direction,
wherein the data lines comprise a first data line and a second data line in the first bypass area and adjacent to each other in the first direction, a third data line and a fourth data line in the second bypass area and adjacent to each other in the first direction, and a fifth data line in the second bypass area and spaced further from the first data line than the third data line in the first direction,
wherein the bridge lines comprise a first bridge line and a second bridge line adjacent in the second direction and overlapping the first bypass area and the second bypass area, and a third bridge line and a fourth bridge line adjacent in the second direction, spaced further from the sub-region than the second bridge line, and overlapping the first bypass area and the second bypass area,
wherein the first bridge line, the second bridge line, the third bridge line, and the fourth bridge line respectively comprise a first bypass bridge line, a second bypass bridge line, a third bypass bridge line, and a fourth bypass bridge line spaced apart from an edge of the display area,
wherein the auxiliary lines comprise a first auxiliary line adjacent to the third data line on one side in the first direction, a second auxiliary line adjacent to the third data line on another side in the first direction, a third auxiliary line adjacent to the fifth data line on one side in the first direction, and a fourth auxiliary line adjacent to the fifth data line on another side in the first direction,
wherein the first auxiliary line, the second auxiliary line, the third auxiliary line, and the fourth auxiliary line respectively comprise a first bypass auxiliary line, a second bypass auxiliary line, a third bypass auxiliary line, and a fourth bypass auxiliary line extending from one of the edges of the display area,
wherein the first bypass bridge line is electrically connected between the first data line and the first bypass auxiliary line,
wherein the second bypass bridge line is electrically connected between the second data line and the second bypass auxiliary line,
wherein the third bypass bridge line is electrically connected between the third data line and the third bypass auxiliary line,
wherein the fourth bypass bridge line is electrically connected between the fourth data line and the fourth bypass auxiliary line,
wherein an extension length of the fourth bypass bridge line is less than an extension length of the third bypass bridge line, which is less than an extension length of the second bypass bridge line, which is less than an extension length of the first bypass bridge line.
